(19) United States
(12) Patent Application Publication
(10) Pub. No.: US 2008/0083989 A1
(43) Pub. Date: Apr. 10, 2008

(54) Semiconductor Device and Method for Fabricating the Same

(76) Inventors: Nobuo Aoi, Hyogo (JP); Hideo Nakagawa, Shiga (JP); Atsushi Ikeda, Shiga (JP)

Correspondence Address: MCDERMOTT WILL & EMERY LLP, 600 13TH STREET, N.W., WASHINGTON, DC, 20005-3096, US

(21) Appl. No.: 10/578,351

(22) PCT Filed: May 20, 2005
(86) PCT No.: PCT/JP05/09269

§ 371 Date: May 5, 2006

(30) Foreign Application Priority Data
Jun. 21, 2004 (JP) 2004-182692

(51) Int. Cl. H01L 23/48; H01L 21/4763

(52) U.S. Cl. 257/751; 438/643; 257/E23.01; 257/E21.495

(57) ABSTRACT

A semiconductor device includes insulation films (6 and 8) formed over a silicon substrate (1), a buried wire (14) formed in the insulation films (6 and 8), and a barrier metal film (A1) formed between each of the insulation films (6 and 8) and the buried wire (14). The barrier metal film (A1) is formed of a metal oxide film (11), a transition layer (12a) and a metal film (13) stacked in this order in the direction from a side of the barrier metal film (A1) at which the insulation films (6 and 8) exists to a side thereof at which the buried wire (14) exists. The transition layer (12a) is formed of a single atomic layer having substantially an intermediate composition between respective compositions of the metal oxide film (11) and the metal film (13).

### RELATED APPLICATIONS

This application is the U.S. National Phase under 35 U.S.C. § 371 of International Application No. PCT/JP2005/009269, filed on May 20, 2005, which in turn claims the benefit of Japanese Application No. 2004-182692, filed on Jun. 21, 2004, the disclosures of which Applications are incorporated by reference herein.

### TECHNICAL FIELD

The present invention relates to a semiconductor device including a metal wire and a method for fabricating the semiconductor device, and more particularly relates to a barrier metal film and a method for forming the barrier metal film.

### BACKGROUND ART

In recent years, as the feature size of semiconductor integrated circuit devices (which will be hereafter referred to as “semiconductor devices”) becomes smaller, a combination of a copper wire and an insulation film having a low dielectric constant, i.e., a so-called low-k film has been adopted as a multi-layer wire of a semiconductor device. With use of such a multi-layer wire, RC delay and power consumption can be reduced. Furthermore, to increase the degree of integration, function and operation speed of a semiconductor device, use of a low-k film having an even lower dielectric constant than that of those presently used is examined.

A copper wire is usually formed using a damascene technique. Damascene techniques include a single damascene technique in which a wire and a via plug are alternately formed and a dual damascene technique in which a wire and a via plug are simultaneously formed.

Hereinafter, a method for forming a multi-layer wire by a damascene technique will be described with reference to FIGS. 16(a) and 16(b).

As shown in FIG. 16(a), a first insulation film 102 is formed on a silicon substrate 101 and then a first copper wire 104 formed of copper and including a first barrier metal film 103 is formed in the first insulation film 102. On the silicon substrate 101, a transistor and the like (not shown) are formed. Subsequently, a dielectric barrier film 105 for preventing diffusion of copper, a second insulation film 106, a third insulation film 107 and a fourth insulation film 108 are formed in this order over the first insulation film 102 and the first copper wire 104.

As the dielectric barrier film 105, a silicon nitride film, a silicon nitride carbide film, a silicon carbide oxide film or the like is used. The dielectric barrier film 105 has the function of preventing diffusion of copper of the first insulation film 104 into the second insulation film 106 and the fourth insulation film 108. The same material as that of dielectric barrier film 105 is used for the third insulation film 107.

Moreover, a silicon oxide film, a fluorine-doped silicon oxide film, a silicon oxide carbide film or an insulation film formed of an organic film is used for the second insulation film 106 and the fourth insulation film 108. Each of these insulation films may be a film formed by chemical vapor deposition or may be a SOD (spin on dielectric) film formed by spin coating.

Next, a via hole 110a is formed in the dielectric barrier film 105, the second insulation film 106 and the third insulation film 107, and a wiring groove 110b is formed in the fourth insulation film 108. Thus, as shown in FIG. 16(a), a recess portion 110c including the via hole 110a and the wiring groove 110b is obtained. The via hole 110a and the wiring groove 110b are preferably formed by the process step of forming a dual damascene wiring groove (i.e., the recess portion 110c including the via hole 110a and the wiring groove 110b) using known lithography, etching, ashing and cleaning. In general, a method in which the via hole 110a is first formed and then the wiring groove (trench) 110b is formed has been widely used (for example, see Patent Reference 1).

Next, as shown in FIG. 16(b), a second barrier metal film 111 and a third barrier metal film 112 are formed by physical vapor deposition (PVD) to cover surfaces of the recess portion 110c.

Next, as shown in FIG. 16(c), a copper seed layer 113 is formed on the third barrier metal film 112 by physical vapor deposition.

Next, as shown in FIG. 16(d), a copper film 114 is formed by copper electroplating using the copper seed layer 113 so as to fill the recess portion 110c and entirely cover surfaces of the third barrier metal film 112.

Next, as shown in FIG. 16(e), part of the copper film 114 located on the fourth insulation film 108, except for part thereof located inside of the recess portion 110c, and parts of the second barrier metal film 111 and the third barrier metal film 112 located on the fourth insulation film 108, except for parts thereof located inside of the recess portion 110c is removed by polishing using chemical mechanical polishing (CMP). Thus, a via plug 115a and a second wire 115b are formed. Note that only one of the via plug 115a and the second wire 115b may be provided. A multi-layer wire can be formed by repeating a series of process steps described above.

In general, copper is easily diffused in an insulation film such as silicon oxide film by heat or an electric field. This tends to be a cause of deterioration of transistor characteristics. Also, copper has poor adhesion with an insulation film. Therefore, a method in which in forming a copper wire, a barrier metal film of a tantalum film or a tantalum nitride film is formed between copper and an insulation film to prevent diffusion of copper into an insulation film and improve adhesion between the insulation film and copper has been proposed (for example, see Patent Reference 2). A tantalum film or a tantalum nitride film is used as a single layer or a lamination structure.

However, when a refractory metal such as tantalum is used as the second barrier metal film 111 formed to be in contact with each of the second, third and fourth insulation films 106, 107 and 108, the problem of poor adhesion between the second barrier metal film 111 formed of a refractory metal and each of the second, third and fourth insulation films 106, 107 and 108 forming the recess portion 110c which is a damascene wire arises. To cope with this problem, a tantalum nitride film is used as the second barrier metal film 111 and a tantalum film is used as the third barrier metal film 112, thereby improving such poor adhesion. However, sufficient adhesion is not achieved.

Moreover, when a tantalum film is formed as the third barrier metal film 112, the tantalum film is oxidized in forming copper by electroplating. Thus, a high resistance tantalum oxide film is formed. Therefore, increase in wire resistance can not be avoided.

Moreover, when a tantalum nitride film is used as the third barrier metal film 112, the tantalum nitride film is not oxidized. However, a tantalum nitride film itself has a high resistance and adhesion thereof with copper is low.

Furthermore, when a titanium film or a titanium nitride film is used as the third barrier metal film 112, the same problem arises as when a tantalum film or a tantalum nitride film is used. Therefore, a metal such as ruthenium and iridium which itself or whose oxide has a low resistance is used as the third barrier metal film 112 to achieve reduction in resistance of the third barrier metal film 112 (see, for example, Patent Reference 3 and Patent Reference 4) and this technique has attracted interest. In general, such metals are formed by atomic layer deposition or chemical vapor deposition.

(Patent Reference 1) Japanese Laid-Open Publication No. 10-223755

(Patent Reference 2) Japanese Laid-Open Publication No. 2002-43419

(Patent Reference 3) Japanese Patent Publication No. 3409831

(Patent Reference 4) Japanese Laid-Open Publication No. 2002-75994

### DISCLOSURE OF INVENTION

### Problems that the Invention is to Solve

However, when a refractory metal film such as tantalum and ruthenium is used as a barrier metal film, adhesion between an insulation film in which a recess portion for a damascene wire is formed and the barrier metal film of the refractory metal film becomes poor. Although such poor adhesion can be improved by forming a metal nitride film between the barrier metal film of a refractory metal film and the insulation film, compared to the case where the barrier metal film of a refractory metal is formed directly on the insulation film, a resistance is increased.

In view of the above-described problems, it is an object of the present invention to provide a semiconductor device including a barrier metal film with a low resistance and excellent adhesion with each of an insulation film and a wire and a method for fabricating the semiconductor device.

### Means of Solving the Problems

To achieve the above-described object, a first semiconductor device according to the present invention is characterized in that the semiconductor device includes: an insulation film formed on a substrate; a buried wire formed in the insulation film; and a barrier metal film formed between the insulation film and the buried wire, and the barrier metal film is formed of a metal oxide film, a transition layer and a metal film stacked in this order in the direction from a side of the barrier metal film at which the insulation film exists to a side thereof at which the buried wire exists, and the transition layer is formed of a single atomic layer having substantially an intermediate composition between respective compositions of the metal oxide film and the metal film.

In the first semiconductor device of the present invention, the transition layer having substantially the intermediate composition between the respective compositions of the metal oxide film and the metal film exists at an interface between the metal oxide film and the metal film. Thus, compared to the case where the transition layer does not exist at the interface between the metal oxide film and the metal film, adhesion between the metal oxide film and the metal film is remarkably improved. Furthermore, since the transition layer is formed of a single atomic layer, in addition to improvement of adhesion between the metal oxide film and the metal film, a barrier metal film can be formed so as to have a small thickness by reducing the thickness of the transition layer to an absolute minimum even when the barrier metal film has a lamination structure, so that a resistance of a wire can be reduced. Therefore, a highly reliable semiconductor device including a multi-layer wire with a low resistance and excellent adhesion can be achieved.

A second semiconductor device according to the present invention is characterized in that the semiconductor device includes: an insulation film formed on a substrate; a buried wire formed in the insulation film; and a barrier metal film formed between the insulation film and the buried wire, the barrier metal film is formed of a metal oxide film, a transition layer and a metal film stacked in this order in the direction from a side of the barrier metal film at which the insulation film exists to a side thereof at which the buried wire exists, and the transition layer is formed of a plurality of atomic layers having substantially an intermediate composition between respective compositions of the metal oxide film and the metal film.

In the second semiconductor device of the present invention, the transition layer having substantially the intermediate composition between the respective compositions of the metal oxide film and the metal film exists at an interface between the metal oxide film and the metal film. Thus, compared to the case where the transition layer does not exist at the interface between the metal oxide film and the metal film, adhesion between the metal oxide film and the metal film is remarkably improved. Accordingly, a barrier metal film having a small thickness and excellent adhesion can be formed. Furthermore, since the transition layer is formed of a plurality of atomic layers, adhesion is further improved, compared to the case where the transition layer provided between the metal oxide film and the metal film is formed of a single atomic layer. Moreover, the composition of the transition layer varies stepwise, so that adhesion is further improved. Therefore, a highly reliable semiconductor device including a multi-layer wire with a low resistance and excellent adhesion can be achieved.

In each of the first and second semiconductor devices of the present invention, it is preferable that a metal forming the metal oxide film and a metal forming the metal film are different elements.

Thus, in a layer structure of a metal film/a transition layer/a metal oxide film/an insulation film, adhesion between the insulation film and the metal oxide film can be optimized according to a kind of the insulation film without degrading adhesion between the metal oxide film and the metal film. Therefore, a highly reliable semiconductor device including a multi-layer wire with a low cost and excellent adhesion can be achieved.

In each of the first and second semiconductor devices of the present invention, it is preferable that a metal forming the metal oxide film and a metal forming the metal film are the same element.

Thus, in a layer structure of a metal film/a transition layer/a metal oxide film, adhesion at an interface between the transition layer and the metal film and at an interface between the metal oxide film and the transition layer can be improved. Therefore, a highly reliable semiconductor device including a multi-layer wire with a low resistance and excellent adhesion can be achieved.

A third semiconductor device according to the present invention is characterized in that the semiconductor device includes: an insulation film formed on a substrate; a buried wire formed in the insulation film; and a barrier metal film formed between the insulation film and the buried wire, the barrier metal film is formed of a transition layer and a metal film stacked in this order in the direction from a side of the barrier metal film at which the insulation film exists to a side thereof at which the buried wire exists, and the transition layer is formed of a single atomic layer including a metal oxide and a metal forming the metal film and having substantially an intermediate composition between respective compositions of the metal oxide and the metal film.

In the third semiconductor device of the present invention, the transition layer having substantially the intermediate composition between the respective compositions of the metal oxide and the metal film exists at an interface between the insulation film and the metal film. Thus, compared to the case where the transition layer does not exist at the interface between the insulation film and the metal film, adhesion between the insulation film and the metal film can be remarkably improved. Furthermore, since the transition layer is formed of a single atomic layer, in addition to improvement of adhesion between the insulation film and the metal film, a barrier metal film can be formed so as to have a small thickness, even when the barrier metal film has a lamination structure, by reducing the thickness of the transition layer to an absolute minimum, so that a resistance of a wire can be reduced. Therefore, a highly reliable semiconductor device including a multi-layer wire with a low resistance and excellent adhesion can be achieved.

A fourth semiconductor device according to the present invention is characterized in that the semiconductor device includes: an insulation film formed on a substrate; a buried wire formed in the insulation film; and a barrier metal film formed between the insulation film and the buried wire, the barrier metal film is formed of a transition layer and a metal film stacked in this order in the direction from a side of the barrier metal film at which the insulation film exists to a side thereof at which the buried wire exists, and the transition layer is formed of a plurality of atomic layers including metal oxide and a metal forming the metal film and having substantially an intermediate composition between respective compositions of the metal oxide and the metal film.

In the fourth semiconductor device of the present invention, the transition layer having substantially the intermediate composition between the respective compositions of the metal oxide and the metal film exists at an interface between the insulation film and the metal film. Thus, compared to the case where the transition layer does not exist at the interface between the insulation film and the metal film, adhesion between the insulation film and the metal film can be remarkably improved. Accordingly, a barrier metal film having a small thickness and excellent adhesion can be formed. Furthermore, as another effect, the transition layer is formed of a plurality of atomic layers, so that adhesion is further improved, compared to the case where the transition layer provided between the insulation film and the metal film is formed of a single atomic layer. Moreover, the composition of the transition layer varies stepwise, so that adhesion is further improved. Therefore, a highly reliable semiconductor device including a multi-layer wire with a low resistance and excellent adhesion can be achieved.

In each of the third and fourth semiconductor devices of the present invention, it is preferable that a metal forming the metal oxide and a metal forming the metal film are different elements.

Thus, in a layer structure of a metal film/a transition layer/an insulation film, adhesion between the insulation film and the transition layer can be optimized according to a kind of the insulation film without degrading adhesion between the transition layer and the metal film. Therefore, a highly reliable semiconductor device including a multi-layer wire with a low resistance and excellent adhesion can be achieved.

In each of the third and fourth semiconductor devices of the present invention, it is preferable that a metal forming the metal oxide and a metal forming the metal film are the same element.

Thus, in a layer structure of a metal film/a transition layer, adhesion at an interface between the transition layer and the metal film can be improved. Therefore, a highly reliable semiconductor device including a multi-layer wire with a low resistance and excellent adhesion can be achieved.

A fifth semiconductor device according to the present invention is characterized in that the semiconductor device includes: an insulation film formed on a substrate; a buried wire formed in the insulation film; and a barrier metal film formed between the insulation film and the buried wire, the barrier metal film contains oxygen as a component element, and a concentration of oxygen contained in the barrier metal film continuously varies in a film thickness direction of the barrier metal film.

In the fifth semiconductor device of the present invention, an oxygen concentration in the barrier metal film containing oxygen as a component element continuously varies in a film thickness direction from a surface of the barrier metal film which is in contact with the insulation film to a surface thereof which is in contact with the buried wire. Thus, the barrier metal film does not have an interface at which a composition is remarkably changed, so that the strength of the second barrier metal film itself can be largely improved. Thus, a highly reliable semiconductor device including a multi-layer wire with a low resistance and excellent adhesion can be achieved.

A method for fabricating a first semiconductor device according to the present invention is characterized in that the method includes the steps of: forming a recess portion in an insulation film provided on a substrate; forming a barrier metal film including a metal oxide film, a transition layer and a metal film stacked in this order so that the barrier metal film covers surfaces of the recess portion; and forming a buried wire on the barrier metal film so that the recess portion is filled, and the step of forming the barrier metal film includes the step of performing a single cycle of deposition by atomic layer deposition, thereby forming the transition layer of a single atomic layer having substantially an intermediate composition between respective compositions of the metal oxide film and the metal film.

According to the first semiconductor fabrication method of the present invention, a transition layer of a single atomic layer having substantially an intermediate composition between respective compositions of a metal oxide film and a metal film can be formed at an interface between the metal oxide film and the metal film in a simple manner. Thus, compared to the case where the transition layer does not exist at the interface between the metal oxide film and the metal film, adhesion between the metal oxide film and the metal film can be remarkably improved. Furthermore, since the transition layer is formed of a single atomic layer, in addition to improvement of adhesion between the metal oxide film and the metal film, a barrier metal film can be formed so as to have a small thickness, even when the barrier metal film has a lamination structure, by reducing the thickness of the transition layer to an absolute minimum, so that a resistance of a wire can be reduced. Therefore, a highly reliable semiconductor device including a multi-layer wire with a low resistance and excellent adhesion can be fabricated.

A second method for fabricating a semiconductor device according to the present invention is characterized in that the method includes the steps of: forming a recess portion in an insulation film provided on a substrate; forming a barrier metal film including a metal oxide film, a transition layer and a metal film stacked in this order so that the barrier metal film covers surfaces of the recess portion; and forming a buried wire on the barrier metal film so that the recess portion is filled, the step of forming the barrier metal film includes the step of performing a plurality of cycles of deposition by atomic layer deposition, thereby forming the transition layer including a plurality of atomic layers having substantially an intermediate composition between respective compositions of the metal oxide film and the metal film.

According to the second semiconductor device fabrication method according to the present invention, a transition layer of a plurality of atomic layers having substantially an intermediate composition between respective compositions of a metal oxide film and a metal film can be formed in a simple manner. Thus, compared to the case where the transition layer does not exist at an interface between the metal oxide film and the metal film, adhesion between the metal oxide film and the metal film is remarkably improved. Accordingly, a barrier metal film having a small thickness and excellent adhesion can be formed. Furthermore, as another effect, the transition layer is formed of a plurality of atomic layers, so that adhesion is further improved, compared to the case where the transition layer provided between the insulation film and the metal film is formed of a single atomic layer. Moreover, for example, by changing film formation conditions or a source gas stepwise in each cycle of a plurality of cycles of deposition by atomic layer deposition, the composition of the transition layer can be made to vary stepwise. Accordingly, adhesion can be further improved. Therefore, a highly reliable semiconductor device including a multi-layer wire with a low resistance and excellent adhesion can be fabricated.

In each of the first and second semiconductor fabrication methods of the present invention, it is preferable that a metal forming the metal oxide film and a metal forming the metal film are different elements.

Thus, a metal oxide film, a transition layer and a metal film can be continuously formed, for example, only by changing film formation conditions or a source gas. Accordingly, a barrier metal film having excellent adhesion can be formed, so that the first or second semiconductor device of the present invention can be fabricated in a simple manner.

In each of the first and second semiconductor fabrication methods of the present invention, it is preferable that a metal forming the metal oxide film and a metal forming the metal film are the same element.

Thus, a metal oxide film, a transition layer and a metal film can be continuously formed, for example, only by changing film formation conditions. Thus, a barrier metal film having excellent adhesion can be formed, so that the first or second semiconductor device of the present invention can be fabricated in a simple manner.

A third method for fabricating a semiconductor device according to the present invention is characterized in that the method includes the steps of: forming a recess portion in an insulation film provided on a substrate; forming a barrier metal film including a transition layer and a metal film stacked in this order so that the barrier metal film covers surfaces of the recess portion; and forming a buried wire on the barrier metal film so that the recess portion is filled, the step of forming the barrier metal film includes the step of performing a single cycle of deposition by atomic layer deposition, thereby forming the transition layer made of a single atomic layer including a metal oxide and a metal forming the metal film and having substantially an intermediate composition between respective compositions of the metal oxide and the metal film.

According to the third semiconductor fabrication method of the present invention, a transition layer having substantially an intermediate composition between respective compositions of metal oxide and a metal can be formed at an interface between the insulation film and the metal film in a simple manner. Thus, compared to the case where the transition layer does not exist at the interface between the insulation film and the metal film, adhesion between the insulation film and the metal film is remarkably improved. Furthermore, since the transition layer is formed of a single atomic layer, in addition to improvement of adhesion between the insulation film and the metal film, a barrier metal film can be formed so as to have a small thickness, even when the barrier metal film has a lamination structure, by reducing the thickness of the transition layer to an absolute minimum, so that a resistance of a wire can be reduced. Therefore, a highly reliable semiconductor device including a multi-layer wire with a low resistance and excellent adhesion can be fabricated.

A fourth method for fabricating a semiconductor device according to the present invention is characterized in that the method includes the steps of: forming a recess portion in an insulation film provided on a substrate; forming a barrier metal film including a transition layer and a metal film stacked in this order so that the barrier metal film covers surfaces of the recess portion; and forming a buried wire on the barrier metal film so that the recess portion is filled, the step of forming the barrier metal film includes the step of performing a plurality of cycles of deposition by atomic layer deposition, thereby forming the transition layer including a plurality of atomic layers made of a metal oxide and a metal forming the metal film and having an intermediate composition between respective compositions of the metal oxide and the metal film.

According to the fourth semiconductor device fabrication method of the present invention, a transistor layer formed of a plurality of atomic layers and having substantially an intermediate composition between respective compositions of a metal oxide and a metal film can be formed at an interface between the insulation film and the metal film in a simple manner. Thus, compared to the case where the transition layer does not exist in the interface between the insulation film and the metal film, adhesion between the insulation film and the metal film is remarkably improved. Accordingly, a barrier metal film having a small thickness and excellent adhesion can be formed. Furthermore, as another effect, since the transition layer is formed of a plurality of atomic layers, adhesion is further improved, compared to the case where the transition layer provided between the insulation film and the metal film is formed of a single atomic layer. Moreover, for example, by changing film formation conditions or a source gas stepwise in each cycle of a plurality of cycles of deposition by atomic layer deposition, the composition of the transition layer can be made to vary stepwise. Accordingly, adhesion can be further improved. Therefore, a highly reliable semiconductor device including a multi-layer wire with a low resistance and excellent adhesion can be fabricated.

In each of the third and fourth semiconductor device fabrication methods of the present invention, it is preferable that a metal forming the metal oxide and a metal forming the metal film are different elements.

Thus, a transition layer and a metal film can be continuously formed, for example, only by changing film formation conditions and a source gas. Accordingly, a barrier metal film having excellent adhesion can be formed, so that the third or fourth semiconductor device of the present invention can be fabricated in a simple manner.

In each of the third or fourth semiconductor device formation methods of the present invention, it is preferable that the metal forming a metal oxide and a metal forming the metal film are the same element.

Thus, a transition layer and a metal film can be continuously formed, for example, only by changing film formation conditions. Accordingly, a barrier metal film having excellent adhesion can be formed, so that the third or fourth semiconductor device of the present invention can be fabricated in a simple manner.

A fifth method for fabricating a semiconductor device according to the present invention is characterized in that the method includes the steps of: forming a recess portion in an insulation film provided on a substrate; forming a barrier metal film containing oxygen as a component element so that the barrier metal film covers surfaces of the recess portion; and forming a buried wire on the barrier metal film so that the recess portion is filled, the step of forming the barrier metal film includes the step of forming the barrier metal such that a concentration of oxygen contained in the barrier metal film continuously varies in a film thickness direction of the barrier metal film.

According to the fifth semiconductor device fabrication method of the present invention, atomic layer deposition is used. Thus, only by continuously changing film formation conditions, a barrier metal film can be formed such that a concentration of oxygen continuously varies in a film thickness direction from a surface of the barrier metal film which is in contact with an insulation film to a surface thereof which is in contact with a buried wire. Accordingly, the barrier metal film does not have an interface at which a composition is remarkably changed, so that the strength of the second barrier metal film itself can be largely improved. Therefore, a highly reliable semiconductor device including a multi-layer wire with a low resistance and excellent adhesion can be fabricated.

### EFFECTS OF THE INVENTION

According to each of the first through fifth semiconductors and also each of the first through fifth methods for fabricating a semiconductor device, a highly reliable semiconductor device including a multi-layer wire with a low resistance and excellent adhesion can be achieved.

### BRIEF DESCRIPTION OF DRAWINGS

FIG. 1 is a cross-sectional view illustrating relevant part of a structure of a semiconductor device according to a first embodiment of the present invention.

FIG. 2 illustrates a distribution of atomic concentration in a thickness direction of a second barrier metal film according to the first embodiment of the present invention.

FIGS. 3(a) through 3(c) are cross-sectional views of relevant part of a semiconductor device according to the first embodiment of the present invention illustrating respective steps for fabricating the semiconductor device.

FIG. 4 is a cross-sectional view illustrating relevant part of a structure of a semiconductor device according to a second embodiment of the present invention.

FIG. 5 illustrates a distribution of atomic concentration in a thickness direction of a second barrier metal film according to the second embodiment of the present invention.

FIGS. 6(a) through 6(c) are cross-sectional views of relevant part of a semiconductor device according to the second embodiment of the present invention illustrating respective steps for fabricating the semiconductor device.

FIG. 7 is a cross-sectional view illustrating relevant part of a structure of a semiconductor device according to a third embodiment of the present invention.

FIG. 8 illustrates a distribution of atomic concentration in a thickness direction of a second barrier metal film according to the third embodiment of the present invention.

FIGS. 9(a) through 9(c) are cross-sectional views of relevant part of a semiconductor device according to the third embodiment of the present invention illustrating respective steps for fabricating the semiconductor device.

FIG. 10 is a cross-sectional view illustrating relevant part of a structure of a semiconductor device according to a fourth embodiment of the present invention.

FIG. 11 illustrates a distribution of atomic concentration in a thickness direction of a second barrier metal film according to the fourth embodiment of the present invention.

FIGS. 12(a) through 12(c) are cross-sectional views of relevant part of a semiconductor device according to the fourth embodiment of the present invention illustrating respective steps for fabricating the semiconductor device.

FIG. 13 is a cross-sectional view illustrating relevant part of a structure of a semiconductor device according to a fifth embodiment of the present invention.

FIG. 14 illustrates a distribution of atomic concentration in a thickness direction of a second barrier metal film according to the fifth embodiment of the present invention.

FIGS. 15(a) and 15(b) are cross-sectional views of relevant part of a semiconductor device according to the fifth embodiment of the present invention illustrating respective steps for fabricating the semiconductor device.

FIG. 16 is a cross-sectional view illustrating relevant part of a structure of a known semiconductor device.

### BEST MODE FOR CARRYING OUT THE INVENTION

### First Embodiment

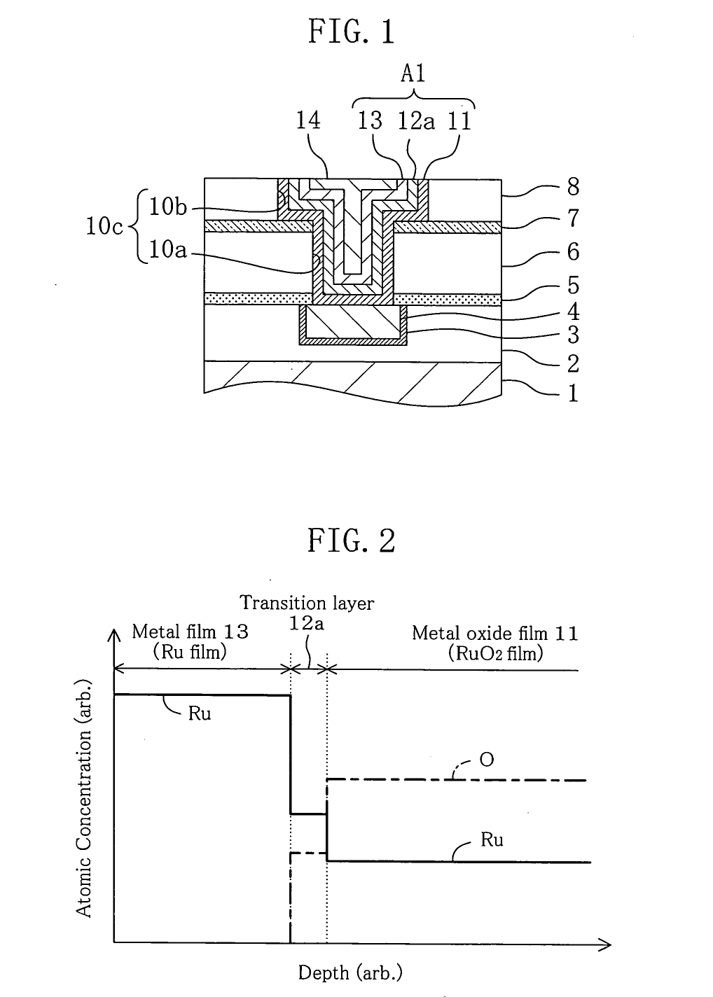

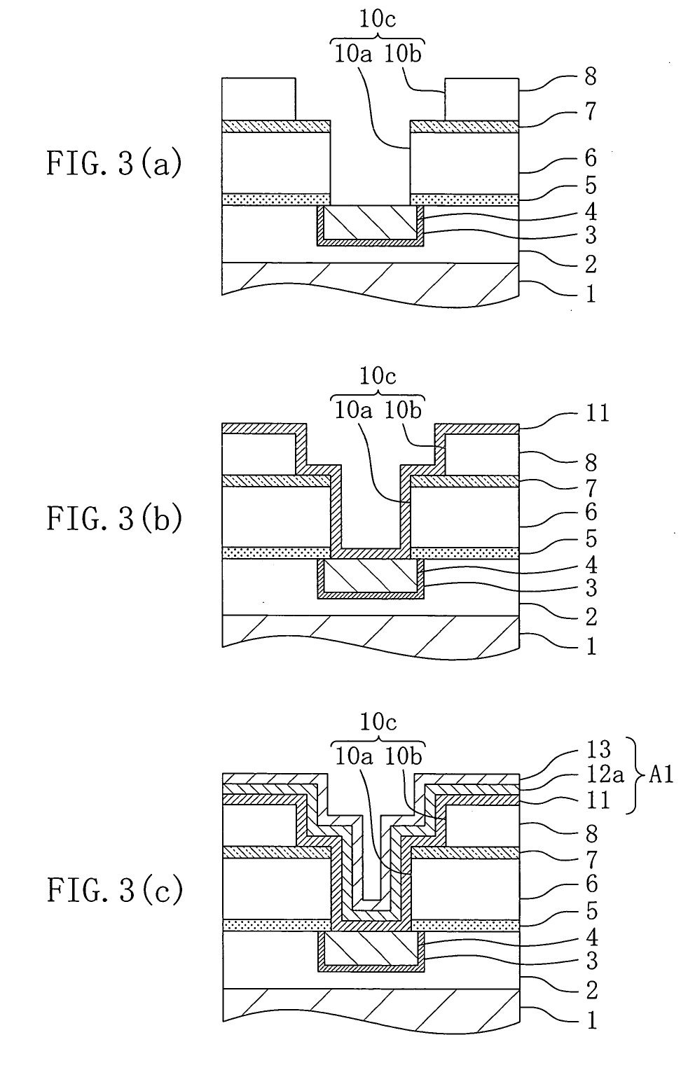

A semiconductor device according to a first embodiment of the present invention and a method for fabricating the semiconductor device will be described with reference to FIG. 1, FIG. 2 and FIGS. 3(a) through 3(c).

FIG. 1 is a cross-sectional view illustrating relevant part of a structure of a semiconductor device according to the first embodiment of the present invention.

As shown in FIG. 1, a first insulation film 2 which is an insulation film of a lower layer is formed on a silicon substrate 1. A first copper wire 4 which is a copper wire of a lower layer including a first barrier metal film 3 is formed in the first insulation film 2. On the silicon substrate 1, a transistor and the like (not shown) are formed. A dielectric barrier film 5 for preventing diffusion of copper, a second insulation film 6, a third insulation film 7 and a fourth insulation film 8 are formed in this order over the first insulation film 2 and the first copper wire 4.

A via hole 10a is formed in the dielectric barrier film 5, the second insulation film 6 and the third insulation film 7 so as to reach the first copper wire 4, and a wiring groove 10b is formed in the fourth insulating film 8 so as to communicate to the via hole 10a. Thus, a recess portion 10c including the via hole 10a and the wiring groove 10b which is to be a dual damascene wiring groove is formed.

Moreover, as shown in FIG. 1, a second barrier metal film A1 is formed on surfaces of the recess portion 10c. The second barrier metal film A1 is formed of a metal oxide film 11 formed on the dielectric barrier film 5, the second insulation film 6, the third insulation film 7 and the fourth insulation film 8 so as to cover the surfaces of the recess portion 10c, a transition layer 12a formed on the metal oxide film 11 and a metal film 13 formed on the transition layer 12a. The transition layer 12a is formed in the vicinity of an interface between the metal oxide film 11 and the metal film 13 and has substantially an intermediate composition between respective compositions of the metal oxide film 11 and the metal film 13. Furthermore, the transition layer 12a is formed of a single atomic layer.

FIG. 2 illustrates a distribution of atomic concentration in a thickness direction of the barrier metal film A1, for example, when a metal forming the metal film 13 is ruthenium (Ru) and the metal oxide film 11 is ruthenium oxide (RuO₂).

As shown in FIG. 2, the transition layer 12a of a single atomic layer is formed between the metal film 13 of ruthenium (Ru) and the metal oxide film 11 of ruthenium oxide (RuO₂). The transition layer 12a has an intermediate composition between the respective compositions of the metal film 13 of ruthenium (Ru) and the metal oxide film 11 of ruthenium oxide (RuO₂). Specifically, a ruthenium (Ru) concentration in the transition layer 12a is an intermediate concentration between a ruthenium (Ru) concentration in the metal film 13 and a ruthenium (Ru) concentration in the metal oxide film 11. Moreover, an oxygen (O) concentration in the transition layer 12a is an intermediate concentration between an oxygen (O) concentration in the metal film 13 (i.e., 0 in this case) and an oxygen (O) concentration of the metal oxide film 11.

Furthermore, a second copper wire 14 which is made of copper and is a wire of an upper layer is formed on the metal film 13 so as to fill the inside of the recess portion 10c. Note that the second copper wire 14 may be a wire, a via plug or a combination of a wire and a via plug. The second copper wire 14 may be formed of a copper alloy containing some other component (for example, a small amount of Si, Al, Mo, Si or the like) than pure copper and copper.

In this case, as the dielectric barrier film 5, a silicon nitride film, a silicon nitride carbide film, a silicon carbide oxide film, a silicon carbide film or a lamination film formed of a combination of these films is preferably used. The dielectric barrier film 5 has the function of preventing diffusion of copper contained in the first copper wire 4 into the second insulation film 6 and the fourth insulation film 8. As the third insulation film 7, the same material as that used for the dielectric barrier film 5 is preferably used. The third insulation film 7 is a film mainly functioning as an etching stopper for forming the wiring groove 10b. When a sufficient etching selection ratio can be obtained between the second insulation film 6 and the fourth insulation film 8 or when etching for forming the wiring groove 10b can be precisely formed, the third insulation film 7 is not necessarily provided.

Moreover, as each of the second insulation film 6 and the fourth insulation film 8, a silicon oxide film, a fluorine-doped silicon oxide film, a silicon oxide carbide film or an insulation film of an organic film is preferably used. Each of these films may be a film formed by chemical vapor deposition or a SOD (spin on dielectric) film formed by spin coating. Moreover, the same material may be used for the second insulation film 6 and the fourth insulation film 8.

As a metal forming the metal oxide film 11, a refractory metal is preferably used. Thus, in the process step of forming a wire of an upper layer after formation of the second copper wire 14, even when heat of about 400° C. is applied, the metal oxide film 11 does not degrade due to the heat treatment. Therefore, a highly reliable semiconductor device can be achieved.

When the metal oxide film 11 has a small thickness, the metal oxide film 11 does not necessarily have conductivity. However, it is preferable that the metal oxide film 11 has conductivity. Hereinafter, the metal oxide film 11 having conductivity will be specifically described.

As a metal forming the metal oxide film 11, titanium (Ti), zirconium (Zr), hafnium (Hf), tantalum (Ta), niobium (Nb), tungsten (W), vanadium (V), molybdenum (Mo), ruthenium (Ru), osmium (Os), rhodium (Rh), iridium (Ir), palladium (Pd) or platinum (Pt) is preferably used.

It is more preferable that as a metal forming the metal oxide film 11, vanadium (V), molybdenum (Mo), ruthenium (Ru), osmium (Os), rhodium (Ru), iridium (Ir), palladium (Pd) or platinum (Pt) is used. Thus, when the metal is oxidized, conductivity is not largely lost (or a resistivity is small), so that the second barrier metal film A1 having a low resistance can be formed.

As a metal forming the metal film 13, titanium (Ti), zirconium (Zr), hafnium (Hf), tantalum (Ta), niobium (Nb), tungsten (W), vanadium (V), molybdenum (Mo), ruthenium (Ru), osmium (Os), rhodium (Rh), iridium (Ir), palladium (Pd) or platinum is preferably used. For example, the resistivity of tantalum is 13 (μΩ·cm), the resistivity of ruthenium is 7.5 (μΩ·cm) and the resistivity of iridium is 6.5 (μΩ·cm).

It is more preferable that vanadium (V), molybdenum (Mo), ruthenium (Ru), osmium (Os), rhodium (Rh), iridium (Ir), palladium (Pd), platinum or the like is used. For example, the resistivity of ruthenium oxide film is 35 (μΩ·cm) and the resistivity of an iridium oxide film is 30 (μΩ·cm). With use of these metals, since the metals do not loose their conductivity (or have a low resistivity) when being oxidized, conductivity is not lost at surfaces of the metal oxide film 11 even when the surfaces of the metal oxide film 11 are oxidized in copper electroplating which will be later described. Accordingly, the second barrier metal film A1 having a low resistance can be formed.

When the second barrier metal film A1 is incorporated in an actual semiconductor device, the second barrier metal film A1 is preferably formed so as to have a thickness of about several to 30 nm in a 65 nm generation semiconductor device. In a 45 nm generation semiconductor device, it is expected that the thickness of the second barrier metal film A1 as a whole has to be about 15 nm or less at most. Note that this is also applied to second barrier metals A2 through A5 which will be described in the following embodiments.

As has been described, in the semiconductor device of the first embodiment of the present invention, the transition layer 12a having substantially the intermediate composition between the respective compositions of the metal film 13 and the metal oxide film 11 exists at the interface between the metal film 13 and the metal oxide film 11. Thus, adhesion between the metal film 13 and the metal oxide film 11 is remarkably improved, compared to the case where the transition layer 12a does not exist at the interface between the metal film 13 and the metal oxide film 13. Furthermore, since the transition layer 12a is formed of a single atomic layer, in addition to improvement of adhesion between the metal film 13 and the metal oxide film 11, a barrier metal film can be formed so as to have a small thickness by reducing the thickness of the transition layer 12a to an absolute minimum even when the barrier metal film has a lamination structure, so that a resistance of a wire can be reduced. Therefore, a highly reliable semiconductor device including a multi-layer wire with a low resistance and excellent adhesion can be achieved.

A metal forming the metal oxide film 11 and a metal forming the metal film 13 may be different elements. In such a case, in a layer structure of the metal film 13/the transition layer 12a/the metal oxide film 11/an insulation film (i.e., each of the second insulation film 6, the third insulation film 7 and the fourth insulation film 8), adhesion between the metal oxide film 11 and the insulation film (i.e., each of the second insulation film 6, the third insulation film 7 and the fourth insulation film 8) can be optimized according to a kind of the insulation film (i.e., each of the second insulation film 6, the third insulation film 7 and the fourth insulation film 8) without degrading adhesion between the metal film 13 and the metal oxide film 11. Therefore, a highly reliable semiconductor device including a multi-layer wire with a low resistance and excellent adhesion can be achieved.

Moreover, a metal forming a metal oxide film and a metal forming a metal film may be the same element. In such a case, adhesion at an interface between the metal film 13 and the transition layer 12a and adhesion at an interface between the transition layer 12a and the metal oxide film 11 can be improved in a layer structure of the metal film 13/the transition layer 12a/the metal oxide film 11. Therefore, a highly reliable semiconductor device including a multi-layer wire with a low resistance and excellent adhesion can be achieved.

Next, a method for fabricating a semiconductor device according to the first embodiment of the present invention will be described with reference to FIG. 2 and FIGS. 3(a) through 3(c). Specifically, a method for fabricating the semiconductor device of FIG. 1 according to the first embodiment of the present invention will be hereinafter described.

FIGS. 3(a) through 3(c) are cross-sectional views of relevant part of a semiconductor device according to the first embodiment of the present invention illustrating respective steps for fabricating the semiconductor device.

First, as shown in FIG. 3(a), a first insulation film 2 is formed on a silicon substrate 1 and then a first copper wire 4 including a first barrier metal film 3 is formed in the first insulation film 2. On the silicon substrate 1, a transistor and the like (not shown) are formed. Subsequently, a dielectric barrier film 5 for preventing diffusion of copper, a second insulation film 6, a third insulation film 7 and a fourth insulation film 8 are formed in this order over the first insulation film 2 and the first copper wire 4. Then, a via hole 10a is formed in the dielectric barrier film 5, the second insulation film 6 and the third insulation film 7 so that a lower end of the via hole 10a reaches the first copper wire 4, and a wiring groove 10b is formed in the fourth insulation film 8 so as to communicate to the via hole 10a. Thus, a recess portion 10c including the via hole 10a and the wiring groove 10b for dual damascene is formed.

The recess portion 10c including the via hole 10a and the wiring groove 10b is preferably formed by a dual damascene formation method disclosed, for example, in Japanese Laid-Open Publication No. 2002-75994 or the like using known lithography, etching, ashing, and cleaning.

Next, as shown in FIG. 3(b), a metal oxide film 11 is formed on the second insulation film 6, the third insulation film 7 and the fourth insulation film 8 so as to cover surfaces of the recess portion 10c. In this case, the metal oxide film 11 is preferably formed by atomic layer deposition (ALD), chemical vapor deposition (CVD), physical vapor deposition (PVD) or like film formation method.

Next, as shown in FIG. 3(c), a single cycle of deposition is performed by atomic layer deposition, thereby forming a transition layer 12a on the metal oxide film 11. Subsequently, a metal film 13 is formed by atomic layer deposition or physical vapor deposition. Thus, a second barrier metal film A1 including the metal oxide film 11, the transition layer 12a and the metal film 13 is formed. In this case, the transition layer 12a has substantially an intermediate composition between respective compositions of the metal film 13 and the metal oxide film 11.

Hereinafter, a method for forming the second barrier metal film A1, for example, in the case where a metal forming the metal film 13 is ruthenium (Ru) and the metal oxide film 11 is ruthenium oxide (RuO₂) will be described in detail.

A known atomic layer deposition technique (Journal of The Electrochemical Society, 151, G109-G112 (2004)) is used to form the metal oxide film 11, the transition layer 12a and the metal film 13 which together form the second barrier metal film A1. Conditions for film formation in this case are as follows. For example, Ru(EtCp)₂ (bis(ethylcyclopentadienyl)ruthenium) gas is used as a source gas of ruthenium (Ru). Where the source gas is heated to 80° C., the source gas is diluted with Ar gas of 50 mL/min (standard temperature and pressure, dry) for use. The temperature of a substrate is 250° C. and the degree of vacuum is 4.66×10² Pa. As oxygen gas, a gas obtained by mixing Ar gas of 100 mL/min (standard temperature and pressure, dry) to oxygen gas of 70 mL/min (standard temperature and pressure, dry) is used. An arbitrary composition in the range from metal ruthenium to ruthenium oxide can be obtained by changing a pulse time used for supplying Ru(EtCp)₂ gas. The range of the pulse time is from 1 second to 10 seconds. After Ru(EtCp)₂ gas is supplied and then purged for a certain period of time, oxygen gas is supplied. When the supply of oxygen gas is stopped, purge is performed for a certain period of time. Thus, a film of a single atomic layer of Ru and O can be grown. This series of steps is assumed to be a cycle. When metal ruthenium is grown, oxygen gas is not supplied.

For example, with a pulse time of 2 seconds for supplying Ru(EtCp)₂ gas, a ruthenium oxide (RuO₂) film, i.e., the metal oxide film 11 is deposited on the second insulation film 6, the third insulation film 7 and the fourth insulation film 8 to a thickness of 5 nm and then, with a pulse time of 5 seconds for supplying Ru(EtCp)₂, a single atomic layer of the transition layer 12a having an intermediate composition between respective compositions of ruthenium oxide is formed. Next, a ruthenium (Ru) film, i.e., the metal film 13 is deposited to a thickness of 5 nm with a pulse time of 10 seconds for supplying Ru(EtCp)₂. In the second barrier metal film A1 formed in the above-described manner, a distribution of atomic concentration in the film thickness direction is as shown in FIG. 3. In this manner, the composition of the transition layer 12a can be controlled in a simple manner by changing a pulse time.

Next, a copper film is formed over the metal film 13 as well as inside the recess portion 10c by copper electroplating so as to fill the recess portion 10c and then parts of the copper film, the metal film 13, the transition layer 12a and the metal oxide film 11 located on the fourth insulation film 8, except for parts thereof located inside the recess portion 10c, are removed by CMP, thereby forming a second copper wire 14 and a via plug which is part of the second copper wire 14. Thus, a semiconductor device having the structure of FIG. 1 can be obtained. A multi-layer wire can be formed by repeating the process steps from film formation of the dielectric barrier film 5 to CMP.

As has been described, according to the method for fabricating a semiconductor device according to the first embodiment of the present invention, the transition layer 12a of a single atomic layer having substantially the intermediate composition between the respective compositions of the metal film 13 and the metal oxide film 11 can be formed at the interface between the metal film 13 and the metal oxide film 11 in a simple manner. Moreover, the same effects as those of the above-described semiconductor device can be achieved. Specifically, the transition layer 12a having substantially the intermediate composition between the respective compositions of the metal film 13 and the metal oxide film 11 is formed at the interface between the metal film 13 and the metal oxide film 11, so that adhesion between the metal film 13 and the metal oxide film 11 can be remarkably improved, compared to the case where the transition layer 12a does not exist at the interface between the metal film 13 and the metal oxide film 11. Furthermore, since the transition layer 12a is formed of a single atomic layer, in addition to improvement of adhesion between the metal film 13 and the metal oxide film 11, a barrier metal film can be formed so as to have a small thickness by reducing the thickness of the transition layer 12a to an absolute minimum even when the barrier metal film has a lamination structure, so that a resistance of a wire can be reduced. Therefore, a highly reliable semiconductor device including a multi-layer wire with a low resistance and excellent adhesion can be fabricated.

When the metal oxide film 11, the transition layer 12a and the metal film 13 are formed by atomic layer deposition using different metals for a metal forming the metal oxide film 11 and a metal forming the metal film 13, respectively, the metal oxide film 11, the transition layer 12a and the metal film 13 can be continuously formed, for example, only by changing film formation conditions or a source gas. Accordingly, a second barrier metal film having excellent adhesion can be formed.

When the metal oxide film 11, the transition layer 12a and the metal film 13 are formed by atomic layer deposition using the same element for the metal forming the metal oxide film 11 and the metal forming the metal film 13, the metal oxide film 11, the transition layer 12a and the metal film 13 can be continuously formed, for example, only by changing film formation conditions.

### Second Embodiment

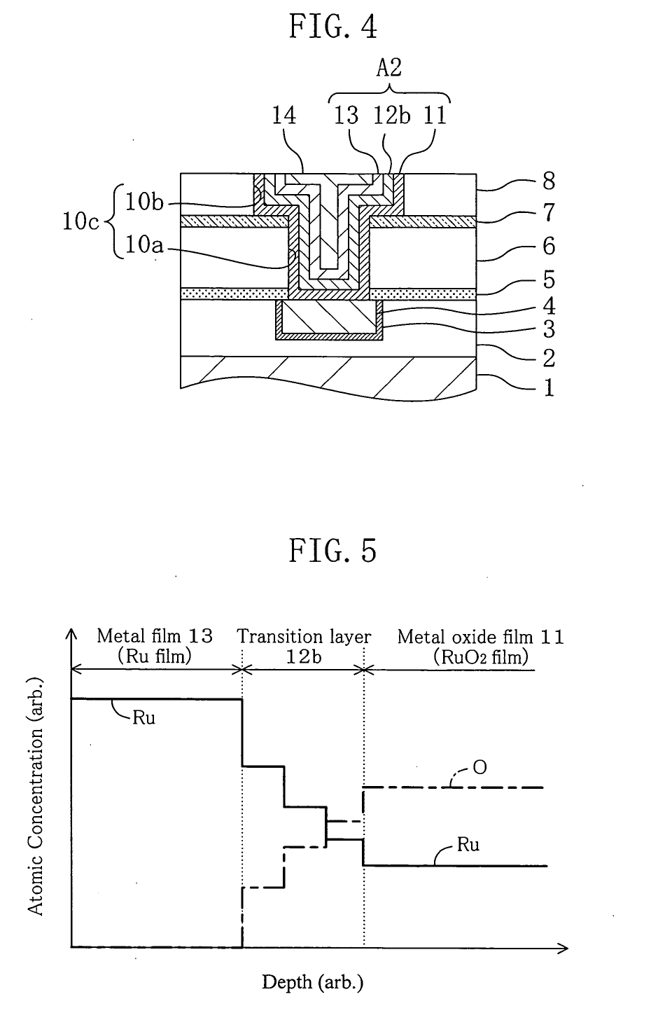

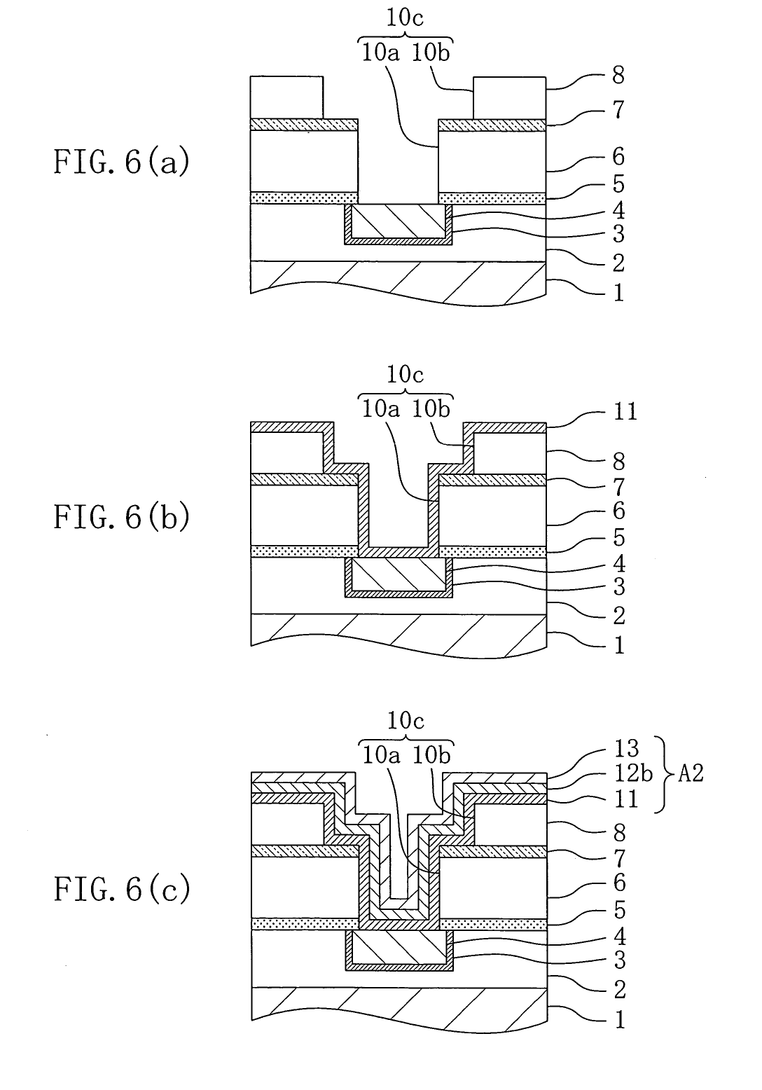

Hereinafter, a semiconductor device according to a second embodiment of the present invention and a method for fabricating the semiconductor device will be described with reference to FIG. 4, FIG. 5 and FIGS. 6(a) through 6(c). The second embodiment has the same part as the first embodiment and therefore the description also shown in the first embodiment is not repeated. Hereinafter, the description will be given focusing on different points from the first embodiment.

FIG. 4 is a cross-sectional view illustrating relevant part of a structure of a semiconductor device according to the second embodiment of the present invention.

As shown in FIG. 4, a second barrier metal film A2 is formed on surfaces of a recess portion 10c. The second barrier metal film A2 is formed of a metal oxide film 11 formed on a dielectric barrier film 5, a second insulation film 6, a third insulation film 7 and a fourth insulation film 8 so as to cover the surfaces of the recess portion 10c, a transition layer 12b formed on the metal oxide film 11 and a metal film 13 formed on the transition layer 12b. The transition layer 12b is formed in the vicinity of an interface between the metal oxide film 11 and the metal film 13 and has substantially an intermediate composition between respective compositions of the metal oxide film 11 and the metal film 13. Furthermore, the transition layer 12b is formed of a plurality of atomic layers.

FIG. 5 illustrates a distribution of atomic concentration in a thickness direction of the barrier metal film A2, for example, when a metal forming the metal film 13 is ruthenium (Ru) and the metal oxide film 11 is ruthenium oxide (RuO₂). The transition layer 12b including three atomic layers is formed between the metal film 13 of ruthenium (Ru) and the metal oxide film 11 of ruthenium oxide (RuO₂). The transition layer 12b has substantially an intermediate composition between respective compositions of the metal film 13 of ruthenium (Ru) and the metal oxide film of ruthenium oxide (RuO₂). Specifically, a ruthenium (Ru) concentration in the transition layer 12b is an intermediate concentration between a ruthenium (Ru) concentration in the metal film 13 and a ruthenium (Ru) concentration in the metal oxide film 11. An oxygen (O) concentration in the transition layer 12b is an intermediate concentration between an oxygen (O) concentration in the metal film 13 (i.e., substantially 0 in this case) and an oxygen concentration in the metal oxide film 11. Furthermore, the ruthenium (Ru) concentration in the transition layer 12b decreases stepwise one atomic layer by one atomic layer in the direction from the metal film 13 of ruthenium (Ru) to the metal oxide film 11 of ruthenium oxide (RuO₂). On the other hand, the oxygen (O) concentration in the transition layer 12b increases stepwise one atomic layer by one atomic layer in the direction from the metal film 13 of ruthenium (Ru) to the metal oxide film 11 of ruthenium oxide (RuO₂). That is, the composition of the transition layer 12b varies stepwise.

As has been described, in the semiconductor device according to the second embodiment of the present invention, the transition layer 12b having substantially the intermediate composition between the respective compositions of the metal film 13 and the metal oxide film 11 exists at the interface between the metal film 13 and the metal oxide film 11, so that adhesion between the metal film 13 and the metal oxide film 11 is dramatically improved, compared to the case where the transition layer 12b does not exist at the interface between the metal film 13 and the metal oxide film 11. Accordingly, a barrier metal film having a small thickness and excellent adhesion can be formed. Furthermore, as another effect, the transition layer 12b is formed of a plurality of atomic layers, so that adhesion is further improved, compared to the case where the transition layer 12b provided between the metal film 13 and the metal oxide film 11 is formed of a single atomic layer. Moreover, the composition of the transition layer 12b varies stepwise, so that adhesion is further improved. Therefore, a highly reliable semiconductor device including a multi-layer wire with a low resistance and excellent adhesion can be achieved.

A metal forming the metal oxide film 11 and a metal forming the metal film 13 may be different elements. In such a case, in a layer structure of the metal film 13/the transition layer 12b/the metal oxide film 11/an insulation film (i.e., each of the second insulation film 6, the third insulation film 7 and the fourth insulation film 8), adhesion between the metal oxide film 11 and the insulation film (i.e., each of the second insulation film 6, the third insulation film 7 and the fourth insulation film 8) can be optimized according to a kind of the insulation film (i.e., each of the second insulation film 6, the third insulation film 7 and the fourth insulation film 8) without degrading adhesion between the metal film 13 and the metal oxide film 11. Therefore, a highly reliable semiconductor device including a multi-layer wire with a low cost and excellent adhesion can be achieved.

Moreover, a metal forming a metal oxide film and a metal forming a metal film may be the same element. In such a case, adhesion at an interface between the metal film 13 and the transition layer 12b and adhesion at an interface between the transition layer 12b and the metal oxide film 11 can be improved in a layer structure of the metal film 13/the transition layer 12b/the metal oxide film 11. Therefore, a highly reliable semiconductor device including a multi-layer wire with a low resistance and excellent adhesion can be achieved.

Next, a method for fabricating a semiconductor device according to the second embodiment of the present invention will be described with reference to FIG. 5 and FIGS. 6(a) through 6(c). Specifically, a method for fabricating the semiconductor device of the second embodiment shown in FIG. 4 will be hereinafter described.

First, in the same manner as shown in FIG. 2(a) in the first embodiment, a recess portion 10c including a via hole 10a and a wiring groove 10b for dual damascene is formed as shown in FIG. 6(a).

Next, as shown in FIG. 6(b), a metal oxide film 11 is formed on the second insulation film 6, the third insulation film 7 and the fourth insulation film 8 so as to cover surfaces of the recess portion 10c. In this case, the metal oxide film 11 is preferably formed by atomic layer deposition (ALD), chemical vapor deposition (CVD), physical vapor deposition (PVD) or like film formation method.

Next, as shown in FIG. 6(c), a single cycle of deposition is performed by atomic layer deposition, thereby forming a transition layer 12b on the metal oxide film 11. Subsequently, a metal film 13 is formed on the transition layer 12b by atomic layer deposition or physical vapor deposition. Thus, a second barrier metal film A2 including the metal oxide film 11, the transition layer 12b and the metal film 13 is formed. In this case, the transition layer 12b has substantially an intermediate composition between the respective compositions of the metal film 13 and the metal oxide film 11.

Hereinafter, a method for forming the second barrier metal A2, for example, in the case where a metal forming the metal film 13 is ruthenium (Ru) and the metal oxide film 11 is ruthenium oxide (RuO₂) will be described in detail.

A known atomic layer deposition technique (Journal of The Electrochemical Society, 151, G109-G112 (2004)) is used to form the metal oxide film 11, the transition layer 12b and the metal film 13 which together form the second barrier metal film A2. Conditions for film formation in this case are as follows. For example, Ru(EtCp)₂ (bis(ethylcyclopentadienyl)ruthenium) gas is used as a source gas of ruthenium (Ru). Where the source gas is heated to 80° C., the source gas is diluted with Ar gas of 50 mL/min (standard temperature and pressure, dry) for use. The temperature of a substrate is 250° C. and the degree of vacuum is 4.66×10² Pa. As oxygen gas, a gas obtained by mixing Ar gas of 100 mL/min (standard temperature and pressure, dry) to oxygen gas of 70 mL/min (standard temperature and pressure, dry) is used. An arbitrary composition in the range from metal ruthenium to ruthenium oxide can be obtained by changing a pulse time used for supplying Ru(EtCp)₂ gas. The range of the pulse time is from 1 second to 10 seconds. After Ru(EtCp)₂ gas is supplied and then purged for a certain period of time, oxygen gas is supplied. When the supply of oxygen gas is stopped, purge is performed for a certain period of time. Thus, a film of a single atomic layer of Ru and O can be grown. This series of steps is assumed to be a cycle. When metal ruthenium is grown, oxygen gas is not supplied.

For example, with a pulse time of 2 seconds for supplying Ru(EtCp)₂ gas, a ruthenium oxide (RuO₂) film, i.e., the metal oxide film 11 is deposited on the second insulation film 6, the third insulation film 7 and the fourth insulation film 8 to a thickness of 5 nm and then, with the pulse time for supplying Ru(EtCp)₂ changed stepwise to 3 seconds, 5 seconds and then 7 seconds, the transition layer 12b having an intermediate composition between respective compositions of ruthenium oxide and ruthenium is formed, thereby obtaining a structure of three atomic layers. Next, a ruthenium (Ru) film, i.e., the metal film 13 is deposited to a thickness of 5 nm with a pulse time of 10 seconds for supplying Ru(EtCp)₂. In the second barrier metal film A2 formed in the above-described manner, a distribution of atomic concentration in the film thickness direction is as shown in FIG. 5. In this manner, the composition of the transition layer 12b can be controlled in a simple manner by changing a pulse time. The composition of the transition layer 12b as a whole preferably has the intermediate composition between ruthenium oxide and ruthenium. An atomic layer of the transition layer 12b located closest to the metal oxide film 11 may be ruthenium oxide. In such a case, the atomic layer located closest to the metal oxide film 11 is preferably grown with a pulse time of 2 seconds for supplying Ru(EtCp)₂.

Next, a copper film is formed over the metal film 13 as well as inside the recess portion 10c by copper electroplating so as to fill the recess portion 10c and then parts of the copper film, the metal film 13, the transition layer 12b and the metal oxide film 11 located on the fourth insulation film 8, except for parts thereof located inside the recess portion 10c, are removed by CMP, thereby forming a second copper wire 14 and a via plug which is part of the second copper wire 14. Thus, a semiconductor device having the structure of FIG. 4 can be obtained. A multi-layer wire can be formed by repeating the process steps from film formation of the dielectric barrier film 5 to CMP.

As described above, according to the method for fabricating a semiconductor device according to the second embodiment of the present invention, the transition layer 12b having substantially the intermediate composition between the respective composition of the metal film 13 and the metal oxide film 11 and including a plurality of atomic layers can be formed in a simple manner at the interface between the metal film 13 and the metal oxide film 11. Moreover, the same effects as those of the semiconductor device of the second embodiment can be achieved. Specifically, the transition layer 12b having substantially the intermediate composition between the respective compositions of the metal film 13 and the metal oxide film 11 is formed at the interface between the metal film 13 and the metal oxide film 11, so that adhesion between the metal film 13 and the metal oxide film 11 can be remarkably improved, compared to the case where the transition layer 12b does not exist at the interface between the metal film 13 and the metal oxide film 11. Accordingly, a barrier metal film having a small thickness and excellent adhesion can be formed. Furthermore, as another effect, since the transition layer 12b is formed of a plurality of atomic layers, adhesion between the metal film 13 and the metal oxide film 11 is further improved, compared to the case where a transition layer provided between the metal film 13 and the metal oxide film 11 is formed of a single atomic layer. Moreover, adhesion can be further improved by changing the composition of the transition layer 12b stepwise. Therefore, a highly reliable semiconductor device including a multi-layer wire with a low resistance and excellent adhesion can be fabricated.

When the metal oxide film 11, the transition layer 12b and the metal film 13 are formed by atomic layer deposition using different metals for a metal forming the metal oxide film 11 and a metal forming the metal film 13, respectively, the metal oxide film 11, the transition layer 12b and the metal film 13 can be continuously formed, for example, only by changing film formation conditions or a source gas. Thus, a second barrier metal film having excellent adhesion can be formed.

When the metal oxide film 11, the transition layer 12b and the metal film 13 are formed by atomic layer deposition using the same element for the metal forming the metal oxide film 11 and the metal forming the metal film 13, the metal oxide film 11, the transition layer 12b and the metal film 13 can be continuously formed, for example, only by changing film formation conditions.

### Third Embodiment

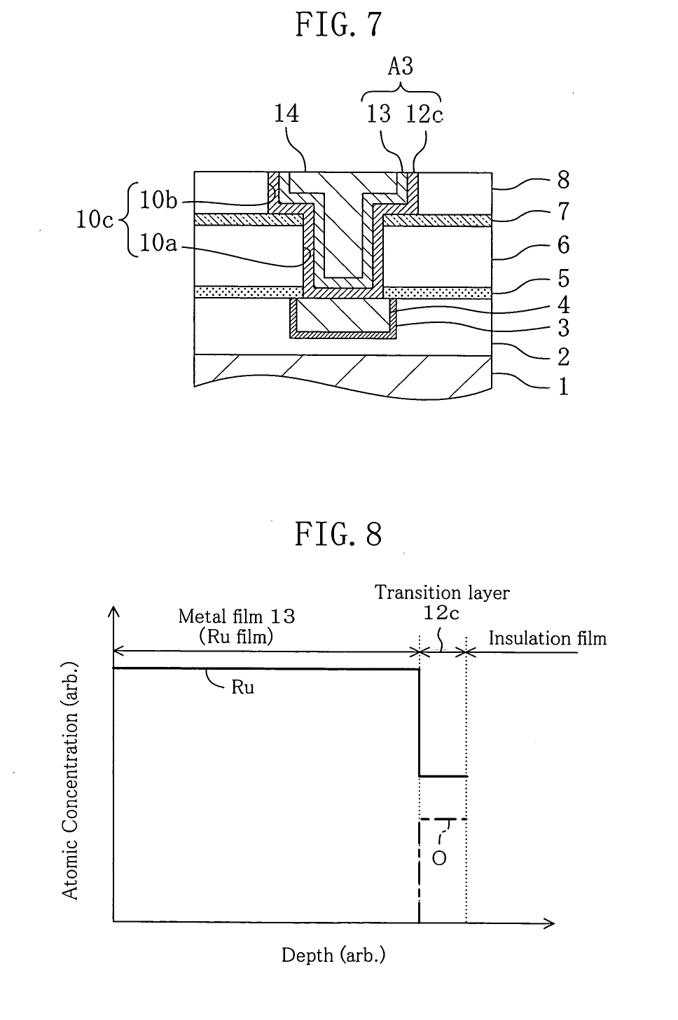

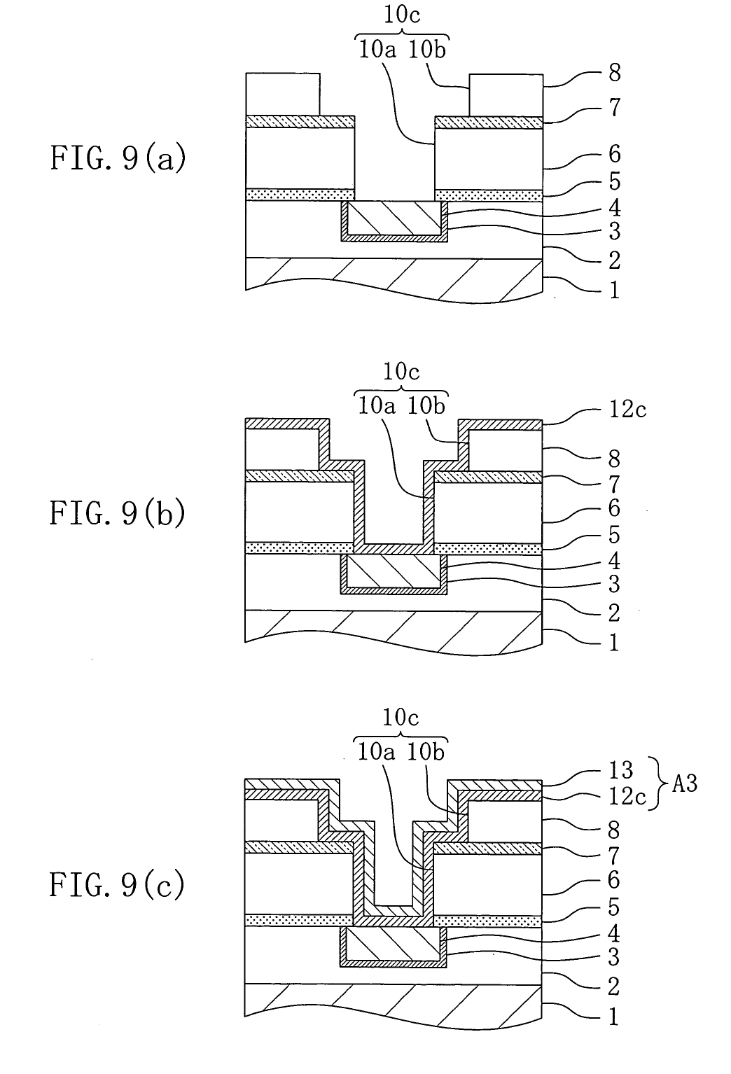

Hereinafter, a semiconductor device according to a third embodiment of the present invention and a method for fabricating the semiconductor device will be described with reference to FIG. 7, FIG. 8 and FIGS. 9(a) through 9(c). The third embodiment has the same part as the first embodiment and therefore the description also shown in the first embodiment is not repeated. Hereinafter, the description will be given focusing on different points from the first embodiment.

FIG. 7 is a cross-sectional view illustrating relevant part of a structure of a semiconductor device according to the third embodiment of the present invention.

As shown in FIG. 7, a second barrier metal A3 is formed on surfaces of a recess portion 10c. The second barrier metal film A3 is formed of a transition layer 12c formed on a dielectric barrier film 5, a second insulation film 6, a third insulation film 7 and a fourth insulation film 8 so as to cover the surfaces of the recess portion 10c and a metal film 13 formed on the transition layer 12c. The transition layer 12c is formed in the vicinity of an interface between an insulation film (i.e., each of the second insulation film 6, the third insulation film 7 and the fourth insulation film 8) and the metal film 13 and has substantially an intermediate composition between respective compositions of a metal oxide and the metal film 13. Furthermore, the transition layer 12c is formed of a single atomic layer.

FIG. 8 illustrates a distribution of atomic concentration in a thickness direction of the barrier metal film A3, for example, when a metal forming the metal film 13 is ruthenium (Ru) and the metal oxide is ruthenium oxide (RuO₂). The transition layer 12c of a single atomic layer is formed between the metal film 13 of ruthenium (Ru) and the insulation film (i.e., each of the second insulation film 6, the third insulation film 7 and the fourth insulation film 8). The transition layer 12c has substantially the intermediate composition between the respective compositions of the metal film 13 of ruthenium (Ru) and the metal oxide of ruthenium oxide (RuO₂). Specifically, a ruthenium (Ru) concentration in the transition layer 12c is an intermediate concentration between a ruthenium (Ru) concentration in the metal film 13 and a ruthenium (Ru) concentration in the metal oxide of ruthenium oxide (RuO₂). An oxygen (O) concentration in the transition layer 12c is an intermediate concentration between an oxygen (O) concentration in the metal film 13 (i.e., substantially 0 in this case) and an oxygen (O) concentration in the metal oxide of ruthenium oxide (RuO₂).

A refractory metal is preferably used as a metal for forming the metal oxide which determines the composition of the transition layer 12c. Thus, in the process step of forming a wire of an upper layer after formation of a second copper wire 14, even when heat of about 400° C. is applied, the transition layer 12c does not degrade due to the heat treatment. Therefore, a highly reliable semiconductor device can be achieved.

Moreover, when the transition layer 12c has a small thickness, the transition layer 12c does not necessarily have conductivity. However, the transition layer 12c preferably has conductivity. Hereinafter, the metal oxide which determines the composition of the transition layer 12c having conductivity will be specifically described.

As a metal forming the metal oxide which determines the composition of the transition layer 12c, titanium (Ti), zirconium (Zr), hafnium (Hf), tantalum (Ta), niobium (Nb), tungsten (W), vanadium (V), molybdenum (Mo), ruthenium (Ru), osmium (Os), rhodium (Rh), iridium (Ir), palladium (Pd) or platinum (Pt) is preferably used.

It is more preferable that as the metal forming the metal oxide which determines the composition of the transition layer 12c, vanadium (V), molybdenum (Mo), ruthenium (Ru), osmium (Os), rhodium (Rh), iridium (Ir), palladium (Pd), platinum (Pt) or the like is used. Thus, when the metal is oxidized, conductivity is not largely lost (or a resistivity is small), so that the second barrier metal film A3 having a low resistance can be formed.

As described above, in the semiconductor device according to the third embodiment of the present invention, the transition layer 12c having substantially the intermediate composition between the respective compositions of the metal film 13 and the metal oxide exists at the interface between the metal film 13 and an insulation film (i.e., each of the second insulation film 6, the third insulation film 7 and the fourth insulation film 8), so that adhesion between the metal film 13 and the insulation film (i.e., each of the second insulation film 6, the third insulation film 7 and the fourth insulation film 8) is remarkably improved, compared to the case where the transition layer 12c does not exist at the interface between the metal film 13 and the insulation film (i.e., each of the second insulation film 6, the third insulation film 7 and the fourth insulation film 8). Furthermore, since the transition layer 12c is formed of a single atomic layer, in addition to improvement of adhesion between the metal film 13 and the insulation film (i.e., each of the second insulation film 6, the third insulation film 7 and the fourth insulation film 8), a barrier metal film can be formed so as to have a small thickness by reducing the thickness of the transition layer 12c to an absolute minimum even when the barrier metal film has a lamination structure, so that a resistance of a wire can be reduced. Therefore, a highly reliable semiconductor device including a multi-layer wire with a low resistance and excellent adhesion can be achieved.

A metal forming the metal oxide which determines the composition of the transition layer 12c and a metal forming the metal film 13 may be different elements. In such a case, in a layer structure of the metal film 13/the transition layer 12c/an insulation film (i.e., each of the second insulation film 6, the third insulation film 7 and the fourth insulation film 8), adhesion between the transition layer 12c and the insulation film (i.e., each of the second insulation film 6, the third insulation film 7 and the fourth insulation film 8) can be optimized according to a kind of the insulation film (i.e., each of the second insulation film 6, the third insulation film 7 and the fourth insulation film 8) without degrading adhesion between the metal film 13 and the transition layer 12c. Therefore, a highly reliable semiconductor device including a multi-layer wire with a low resistance and excellent adhesion can be achieved.

Moreover, a metal forming the metal oxide which determines the composition of the transition layer 12c and a metal forming the metal film 13 may be the same element. In such a case, adhesion at an interface between the metal film 13 and the transition layer 12c can be improved in a layer structure of the metal film 13/the transition layer 12c. Therefore, a highly reliable semiconductor device including a multi-layer wire with a low resistance and excellent adhesion can be achieved.

Next, a method for fabricating a semiconductor device according to the third embodiment of the present invention will be described with reference to FIG. 8 and FIGS. 9(a) through 9(c). Specifically, a method for fabricating the semiconductor device of FIG. 7 according to the third embodiment of the present invention will be hereinafter described.

FIGS. 9(a) through 9(c) are cross-sectional views of relevant part of a semiconductor device according to the third embodiment of the present invention illustrating respective steps for fabricating the semiconductor device.

First, in the same manner as shown in FIG. 2(a) in the first embodiment, a recess portion 10c including a via hole 10a and a wiring groove job for dual damascene is formed as shown in FIG. 9(a).

Next, as shown in FIG. 9(b), a single cycle of deposition is performed by atomic layer deposition, thereby forming a transition layer 12c on the second insulation film 6, the third insulation film 7 and the fourth insulation film 8 so as to cover surfaces of the recess portion 10c.

Next, as shown in FIG. 9(c), a metal film 13 is formed on the transition layer 12c by atomic layer deposition or physical vapor deposition. Thus, the second barrier metal film A3 including the transition layer 12c and the metal film 13 is formed. In this case, the transition layer 12c has substantially an intermediate composition between the respective compositions of the metal film 13 and a metal oxide.

Hereinafter, a method for forming the second barrier metal A3, for example, in the case where a metal forming the metal film 13 is ruthenium (Ru) and the metal oxide which determines the composition of the transition layer 12c is ruthenium oxide (RuO₂) will be described in detail.

A known atomic layer deposition technique (Journal of The Electrochemical Society, 151, G109-G112 (2004)) is used to form the transition layer 12c and the metal film 13 which together form the second barrier metal film A3. Conditions for film formation in this case are as follows. For example, Ru(EtCp)₂ (bis(ethylcyclopentadienyl)ruthenium) gas is used as a source gas of ruthenium (Ru). Where the source gas is heated to 80° C., the source gas is diluted with Ar gas of 50 mL/min (standard temperature and pressure, dry) for use. The temperature of a substrate is 250° C. and the degree of vacuum is 4.66×10² Pa. As oxygen gas, a gas obtained by mixing Ar gas of 100 mL/min (standard temperature and pressure, dry) to oxygen gas of 70 mL/min (standard temperature and pressure, dry) is used. An arbitrary composition in the range from metal ruthenium to ruthenium oxide can be obtained by changing a pulse time used for supplying Ru(EtCp)₂ gas. The range of the pulse time is from 1 second to 10 seconds. After Ru(EtCp)₂ gas is supplied and then purged for a certain period of time, oxygen gas is supplied. When the supply of oxygen gas is stopped, purge is performed for a certain period of time. Thus, a film of a single atomic layer of Ru and O can be grown. This series of steps is assumed to be a cycle. When metal ruthenium is grown, oxygen gas is not supplied.

For example, a single atomic layer of the transition layer 12c having an intermediate composition between respective compositions of ruthenium oxide and ruthenium is formed with a pulse time of 5 seconds for supplying Ru(EtCp)₂. Next, with a pulse time of 10 seconds for supplying Ru(EtCp)₂, a ruthenium (Ru) film, i.e., the metal film 13 is deposited to a thickness of 5 nm. In the second barrier metal film A3 formed in the above-described manner, a distribution of atomic concentration in the film thickness direction is as shown in FIG. 8. In this manner, the composition of the transition layer 12c can be controlled in a simple manner by changing a pulse time.

Next, a copper film is formed over the metal film 13 as well as inside the recess portion 10c by copper electroplating so as to fill the recess portion 10c and then parts of the copper film, the metal film 13 and the transition layer 12c located on the fourth insulation film 8, except for parts thereof located inside the recess portion 10c, are removed by CMP, thereby forming a second copper wire 14 and a via plug which is part of the second copper wire 14. Thus, a semiconductor device having the structure of FIG. 7 can be obtained. A multi-layer wire can be formed by repeating the process steps from film formation of the dielectric barrier film 5 to CMP.

As has been described, according to the method for fabricating a semiconductor device according to the third embodiment of the present invention, the transition layer 12c of a single atomic layer having substantially the intermediate composition between the respective compositions of the metal film 13 and the metal oxide can be formed at an interface between the metal film 13 and the insulation film (i.e., each of the second insulation film 6, the third insulation film 7 and the fourth insulation film 8) in a simple manner. Moreover, the same effects as those of the above-described semiconductor device can be achieved. Specifically, the transition layer 12c having substantially the intermediate composition between the respective compositions of the metal film 13 and the metal oxide is formed at the interface between the metal film 13 and the insulation film (i.e., each of the second insulation film 6, the third insulation film 7 and the fourth insulation film 8), so that adhesion between the metal film 13 and the insulation film (i.e., each of the second insulation film 6, the third insulation film 7 and the fourth insulation film 8) can be remarkably improved, compared to the case where the transition layer 12c does not exist at the interface between the metal film 13 and the insulation film (i.e., each of the second insulation film 6, the third insulation film 7 and the fourth insulation film 8). Furthermore, since the transition layer 12c is formed of a single atomic layer, in addition to improvement of adhesion between the metal film 13 and the insulation film (i.e., each of the second insulation film 6, the third insulation film 7 and the fourth insulation film 8), a barrier metal film can be formed so as to have a small thickness by reducing the thickness of the transition layer 12c to an absolute minimum even when the barrier metal film has a lamination structure, so that a resistance of a wire can be reduced. Therefore, a highly reliable semiconductor device including a multi-layer wire with a low resistance and excellent adhesion can be fabricated.

When the transition layer 12c and the metal film 13 are formed by atomic layer deposition using different metals for a metal forming the metal oxide and a metal forming the metal film 13, respectively, the transition layer 12c and the metal film 13 can be continuously formed, for example, only by changing film formation conditions or a source gas.

When the transition layer 12c and the metal film 13 are formed by atomic layer deposition using the same element for the metal forming the metal oxide and the metal forming the metal film 13, the transition layer 12c and the metal film 13 can be continuously formed, for example, only by changing film formation conditions.

### Fourth Embodiment

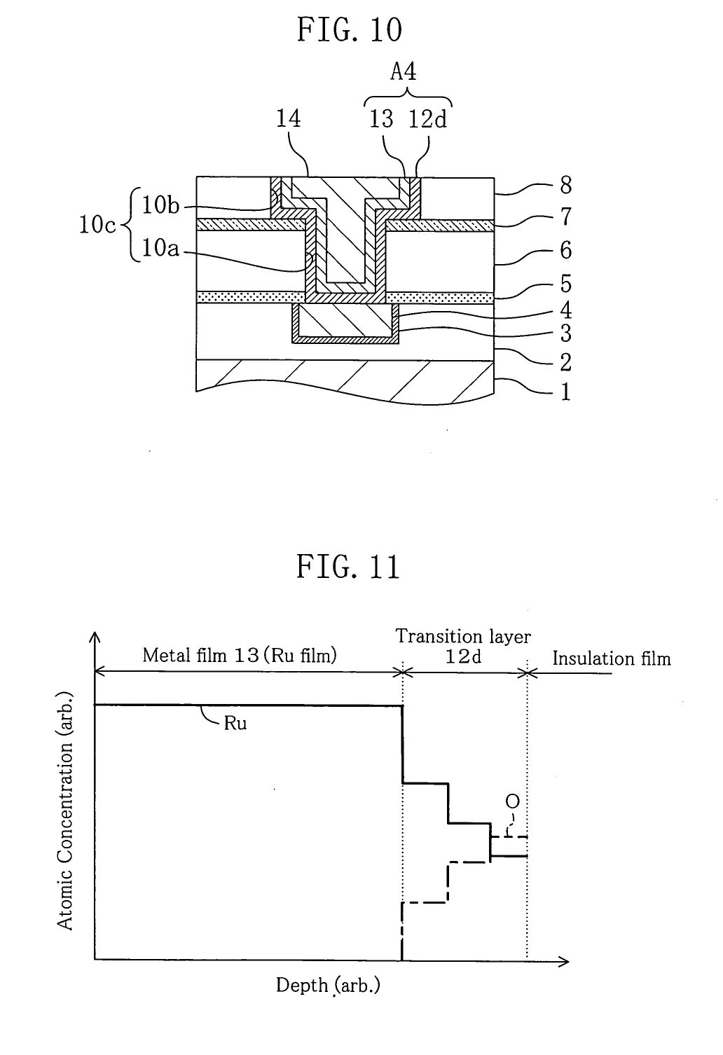

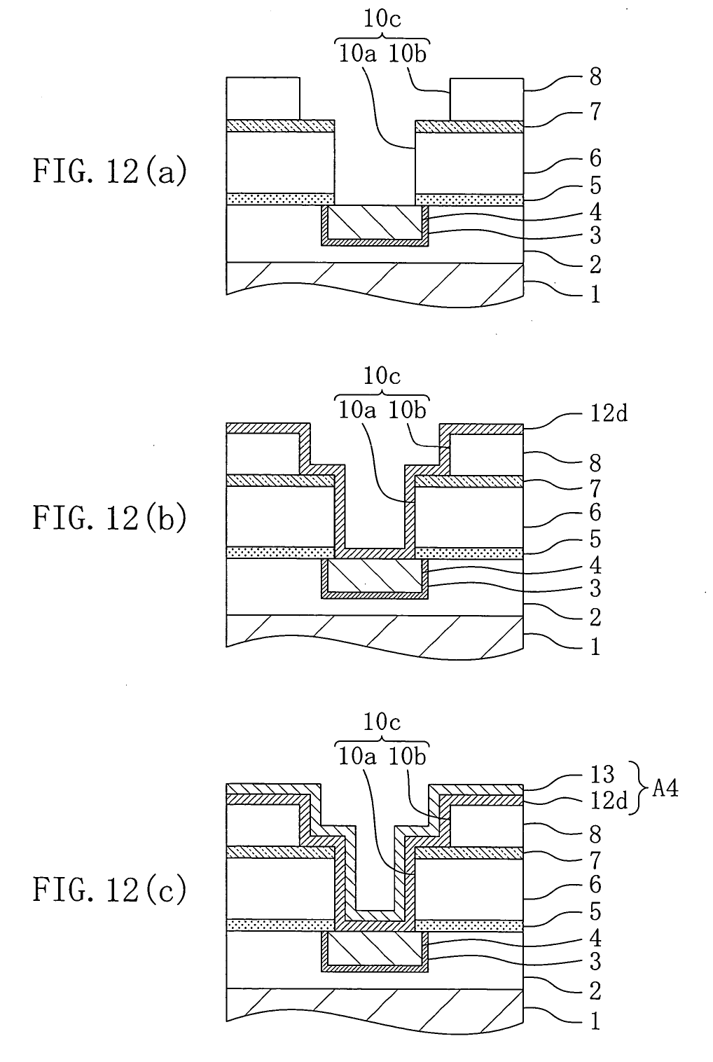

Hereinafter, a semiconductor device according to a fourth embodiment of the present invention and a method for fabricating the semiconductor device will be described with reference to FIG. 10, FIG. 11 and FIGS. 12(a) through 12(c). The fourth embodiment has the same part as the third embodiment and therefore the description also shown in the third embodiment is not repeated. Hereinafter, the description will be given focusing on different points from the third embodiment.

FIG. 10 is a cross-sectional view illustrating relevant part of a structure of a semiconductor device according to the fourth embodiment of the present invention.

As shown in FIG. 10, a second barrier metal film A4 is formed on surfaces of a recess portion 10c. The second barrier metal film A4 is formed of a transition layer 12d formed on a dielectric barrier film 5, a second insulation film 6, a third insulation film 7 and a fourth insulation film 8 so as to cover the surfaces of the recess portion 10c and a metal film 13 formed on the transition layer 12d. The transition layer 12d is formed in the vicinity of an interface between an insulation film (i.e., each of the second insulation film 6, the third insulation film 7 and the fourth insulation film 8) and the metal film 13 and has substantially an intermediate composition between respective compositions of a metal oxide and the metal film 13. Furthermore, the transition layer 12d is formed of a plurality of atomic layers.

FIG. 11 illustrates a distribution of atomic concentration in a thickness direction of the barrier metal film A4, for example, when a metal forming the metal film 13 is ruthenium (Ru) and a metal oxide which determines the composition of the transition layer 12d is ruthenium oxide (RuO₂). The transition layer 12d including three atomic layers is formed between the metal film 13 of ruthenium (Ru) and the insulation film (each of the second insulation film 6, the third insulation film 7 and the fourth insulation film 8). The transition layer 12d has substantially the intermediate composition between the respective compositions of the metal film 13 of ruthenium (Ru) and the metal oxide of ruthenium oxide (RuO₂). Specifically, a ruthenium (Ru) concentration in the transition layer 12d is an intermediate concentration between a ruthenium (Ru) concentration in the metal film 13 and a ruthenium concentration (Ru) in the metal oxide of ruthenium oxide (RuO₂). An oxygen (O) concentration in the transition layer 12d is an intermediate concentration between an oxygen (O) concentration in the metal film 13 (i.e., substantially 0 in this case) and an oxygen (O) concentration in the metal oxide of ruthenium oxide (RuO₂). Furthermore, the ruthenium (Ru) concentration in the transition layer 12d decreases stepwise one atomic layer by one atomic layer in the direction from the metal film 13 of ruthenium (Ru) to the insulation film (each of the second insulation film 6, the third insulation film 7 and the fourth insulation film 9). On the other hand, the oxygen (O) concentration in the transition layer 12d increases stepwise one atomic layer by one atomic layer in the direction from the metal film 13 of ruthenium (Ru) to the insulation film (each of the second insulation film 6, the third insulation film 7 and the fourth insulation film 9). That is, the composition of the transition layer 12d varies stepwise.

As has been described, in the semiconductor device according to the fourth embodiment of the present invention, the transition layer 12d having substantially the intermediate composition between the respective compositions of the metal film 13 and the metal oxide exists at the interface between the metal film 13 and an insulation film (i.e., each of the second insulation film 6, the third insulation film 7 and the fourth insulation film 8), so that adhesion between the metal film 13 and the insulation film (i.e., each of the second insulation film 6, the third insulation film 7 and the fourth insulation film 8) is remarkably improved, compared to the case where the transition layer 12d does not exist at the interface between the metal film 13 and the insulation film (i.e., each of the second insulation film 6, the third insulation film 7 and the fourth insulation film 8). Thus, a barrier metal film having a small thickness and excellent adhesion can be formed. Furthermore, as another effect, the transition layer 12d is formed of a plurality of atomic layers, so that adhesion is further improved, compared to the case where the transition layer 12d provided between the metal film 13 and the insulation film (i.e., the second insulation film 6, the third insulation film 7 and the fourth insulation film 8) is formed of a single atomic layer. Moreover, the composition of the transition layer 12d varies stepwise, so that adhesion is further improved. Therefore, a highly reliable semiconductor device including a multi-layer wire with a low resistance and excellent adhesion can be achieved.

A metal forming the metal oxide which determines the composition of the transition layer 12d and a metal forming the metal film 13 may be different elements. In such a case, in a layer structure of the metal film 13/the transition layer 12d/an insulation film (i.e., each of the second insulation film 6, the third insulation film 7 and the fourth insulation film 8), adhesion between the transition layer 12d and the insulation film (i.e., each of the second insulation film 6, the third insulation film 7 and the fourth insulation film 8) can be optimized according to a kind of the insulation film (i.e., each of the second insulation film 6, the third insulation film 7 and the fourth insulation film 8) without degrading adhesion between the metal film 13 and the transition layer 12d. Therefore, a highly reliable semiconductor device including a multi-layer wire with a low resistance and excellent adhesion can be achieved.

Moreover, a metal forming the metal oxide film which determines the composition of the transition layer 12d and a metal forming the metal film 13 may be the same element. In such a case, adhesion at an interface between the metal film 13 and the transition layer 12d can be improved in a layer structure of the metal film 13/the transition layer 12d. Therefore, a highly reliable semiconductor device including a multi-layer wire with a low resistance and excellent adhesion can be achieved.

Next, a method for fabricating a semiconductor device according to the fourth embodiment of the present invention will be described with reference to FIG. 11 and FIGS. 12(a) through 12(c). Specifically, a method for fabricating the semiconductor device of FIG. 10 according to the fourth embodiment of the present invention will be hereinafter described.

FIGS. 12(a) through 12(c) are cross-sectional views of relevant part of a semiconductor device according to the fourth embodiment of the present invention illustrating respective steps for fabricating the semiconductor device.

First, in the same manner as shown in FIG. 2(a) in the first embodiment, as shown in FIG. 12(a), a recess portion 10c including a via hole 10a and a wiring groove 10b for dual damascene is formed.

As shown in FIG. 12(b), a single cycle of deposition is performed by atomic layer deposition, thereby forming a transition layer 12d is formed on the second insulation film 6, the third insulation film 7 and the fourth insulation film 8 so as to cover surfaces of the recess portion 10c.

Next, as shown in FIG. 12(c), a metal film 13 is formed on the transition layer 12d by atomic layer deposition or physical vapor deposition. Thus, a second barrier metal film A4 including the transition layer 12d and the metal film 13 is formed. In this case, the transition layer 12d has substantially an intermediate composition between the respective compositions of the metal film 13 and a metal oxide.

Hereinafter, a method for forming the second barrier metal A4, for example, in the case where a metal forming the metal film 13 is ruthenium (Ru) and the metal oxide which determines the composition of the transition layer 12d is ruthenium oxide (RuO₂) will be described in detail.

A known atomic layer deposition technique (Journal of The Electrochemical Society, 151, G109-G112 (2004)) is used to form the transition layer 12d and the metal film 13 which together form the second barrier metal film A4. Conditions for film formation in this case are as follows. For example, Ru(EtCp)₂ (bis(ethylcyclopentadienyl)ruthenium) gas is used as a source gas of ruthenium (Ru). Where the source gas is heated to 80° C., the source gas is diluted with Ar gas of 50 mL/min (standard temperature and pressure, dry) for use. The temperature of a substrate is 250° C. and the degree of vacuum is 4.66×10² Pa. As oxygen gas, a gas obtained by mixing Ar gas of 100 mL/min (standard temperature and pressure, dry) to oxygen gas of 70 mL/min (standard temperature and pressure, dry) is used. An arbitrary composition in the range from metal ruthenium to ruthenium oxide can be obtained by changing a pulse time used for supplying Ru(EtCp)₂ gas. The range of the pulse time is from 1 second to 10 seconds. After Ru(EtCp)₂ gas is supplied and then purged for a certain period of time, oxygen gas is supplied. When the supply of oxygen gas is stopped, purge is performed for a certain period of time. Thus, a film of a single atomic layer of Ru and O can be grown. This series of steps is assumed to be a cycle. When metal ruthenium is grown, oxygen gas is not supplied.

For example, with the pulse time for supplying Ru(EtCp)₂ changed in a stepwise manner to 3 seconds, 5 seconds and then 7 seconds, the transition layer 12d having an intermediate composition between respective compositions of ruthenium oxide and ruthenium is formed on the second insulation film 6, the third insulation film 7 and the fourth insulation film 8, thereby obtaining a structure of three atomic layers. Next, with a pulse time of 10 seconds for supplying Ru(EtCp)₂, a ruthenium (Ru) film, i.e., the metal film 13 is deposited to a thickness of 5 nm. In the second barrier metal film A4 formed in the above-described manner, a distribution of atomic concentration in the film thickness direction is as shown in FIG. 11. In this manner, the composition of the transition layer 12d can be controlled in a simple manner by changing a pulse time. The composition of the transition layer 12d as a whole preferably has the intermediate composition between ruthenium oxide and ruthenium. An atomic layer of the transition layer 12d located closest to the metal oxide film 11 may be ruthenium oxide. In such a case, the atomic layer located closest to the metal oxide film 11 is preferably grown with a pulse time of 2 seconds for supplying Ru(EtCp)₂.

Next, a copper film is formed over the metal film 13 as well as inside the recess portion 10c by copper electroplating so as to fill the recess portion 10c and then parts of the copper film, the metal film 13 and the transition layer 12d located on the fourth insulation film 8, except for parts thereof located inside the recess portion 10c, are removed by CMP, thereby forming a second copper wire 14 and a via plug which is part of the second copper wire 14. Thus, a semiconductor device having the structure of FIG. 10 can be obtained. A multi-layer wire can be formed by repeating the process steps from film formation of the dielectric barrier film 5 to CMP.

As has been described, according to the method for fabricating a semiconductor device according to the fourth embodiment of the present invention, the transition layer 12d having substantially the intermediate composition between the respective composition of the metal film 13 and the metal oxide and including a plurality of atomic layers can be formed in a simple manner at the interface between the metal film 13 and the insulation film (i.e., each of the second insulation film 6, the third insulation film 7 and the fourth insulation film 8). Moreover, the same effects as those of the semiconductor device of the fourth embodiment can be achieved. Specifically, the transition layer 12d having substantially an intermediate composition between the respective compositions of the metal film 13 and the metal oxide is formed at the interface between the metal film 13 and the insulation film (i.e., each of the second insulation film 6, the third insulation film 7 and the fourth insulation film 8), so that adhesion between the metal film 13 and the insulation film (i.e., each of the second insulation film 6, the third insulation film 7 and the fourth insulation film 8) can be remarkably improved, compared to the case where the transition layer 12d does not exist at the interface between the metal film 13 and the insulation film (i.e., each of the second insulation film 6, the third insulation film 7 and the fourth insulation film 8). Accordingly, a barrier metal film having a small thickness and excellent adhesion can be formed. Furthermore, as another effect, since the transition layer 12d is formed of a plurality of atomic layers, adhesion between the metal film 13 and the insulation film (i.e., each of the second insulation film 6, the third insulation film 7 and the fourth insulation film 8) is further improved, compared to the case where a transition layer provided between the metal film 13 and the insulation film (i.e., each of the second insulation film 6, the third insulation film 7 and the fourth insulation film 8) is formed of a single atomic layer. Moreover, adhesion can be further improved by changing the composition of the transition layer 12d stepwise. Therefore, a highly reliable semiconductor device including a multi-layer wire with a low resistance and excellent adhesion can be fabricated.

When the transition layer 12d and the metal film 13 are formed by atomic layer deposition using different metals for a metal forming the metal oxide and a metal forming the metal film 13, respectively, the transition layer 12d and the metal film 13 can be continuously formed, for example, only by changing film formation conditions or a source gas.

When the transition layer 12d and the metal film 13 are formed by atomic layer deposition using the same element for the metal forming the metal oxide and the metal forming the metal film 13, the transition layer 12d and the metal film 13 can be continuously formed, for example, only by changing film formation conditions.

### Fifth Embodiment

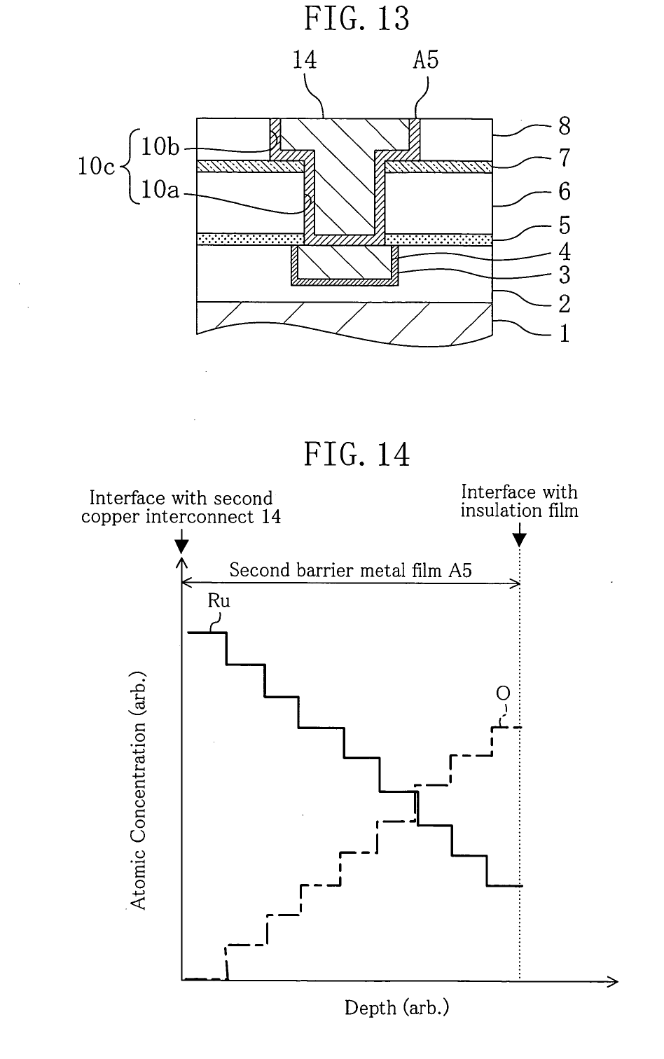

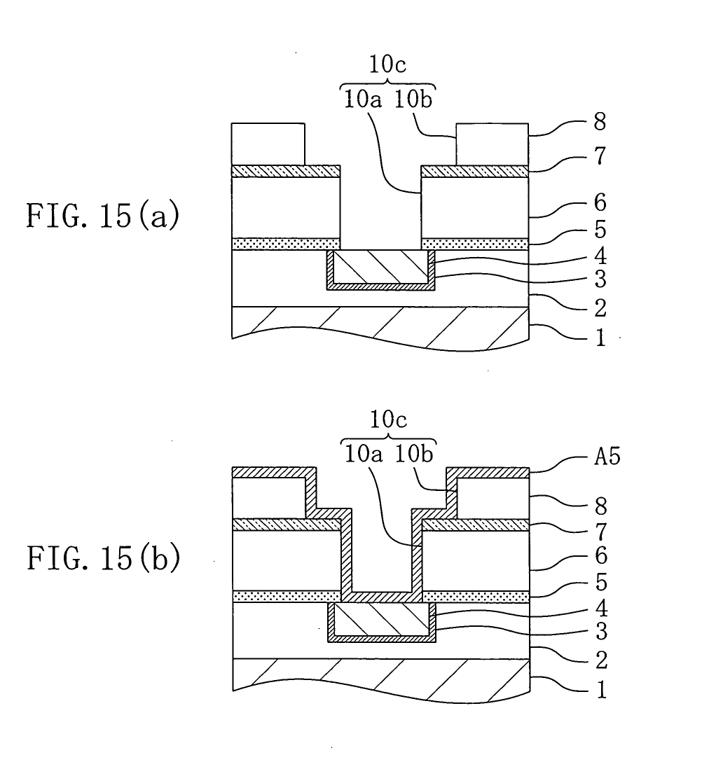

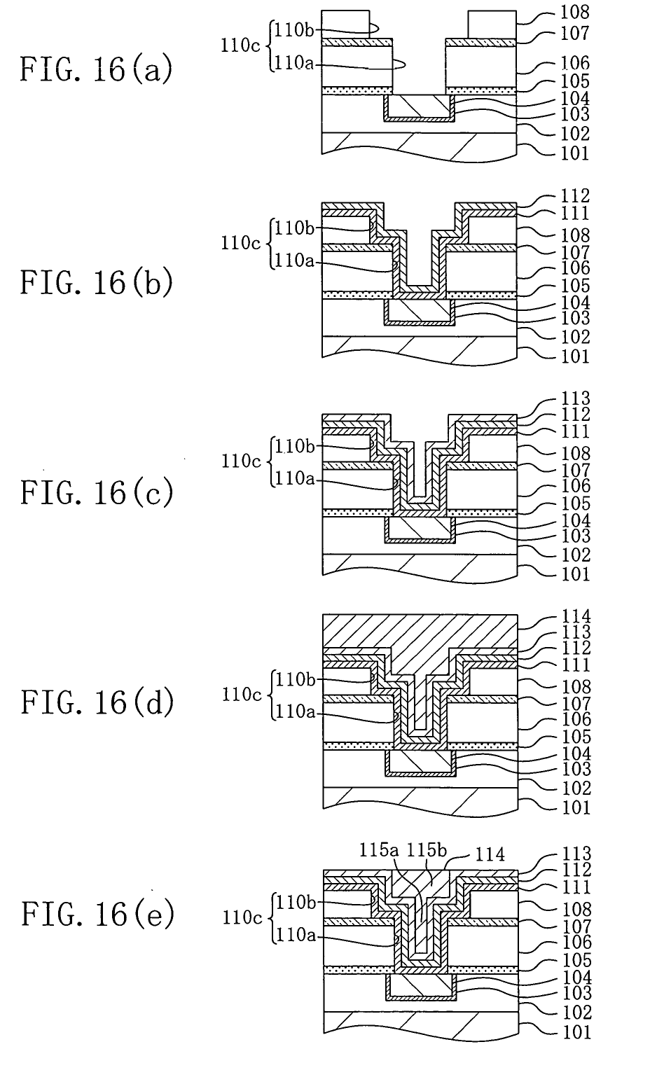

Hereinafter, a semiconductor device according to a fifth embodiment of the present invention and a method for fabricating the semiconductor device will be described with reference to FIG. 13, FIG. 14 and FIGS. 15(a) through 15(c). The fifth embodiment has the same part as the first embodiment and therefore the description also shown in the first embodiment is not repeated. Hereinafter, the description will be given focusing on different points from the first embodiment.

FIG. 13 is a cross-sectional view illustrating relevant part of a structure of a semiconductor device according to the fifth embodiment of the present invention.

As shown in FIG. 13, a second barrier metal film A5 is formed on surfaces of a recess portion 10c. The second barrier metal film A5 is formed of a film containing oxygen as a component element. The oxygen concentration in the second barrier metal film A5 continuously varies in the film thickness direction from an insulation film (i.e., a second insulation film 6, a third insulation film 7 and a fourth insulation film 8) to a second copper wire 14.

FIG. 14 illustrates a distribution of atomic concentration in a thickness direction of the barrier metal film A5, for example, when the second barrier metal film A5 is a film in which an oxygen distribution continuously varies from ruthenium (Ru) to ruthenium oxide (RuO₂). A ruthenium (Ru) layer is formed in the vicinity of an interface between the second copper wire 14 and the second barrier metal film A5. A ruthenium oxide (RuO₂) layer is formed in the vicinity of an interface between the second barrier metal film A5 and an insulation film (i.e., each of the second insulation film 6, the third insulation film 7 and the fourth insulation film 8). In the direction from the second copper wire 14 to the insulation film (i.e., each of the second insulation film 6, the third insulation film 7 and the fourth insulation film 8), while the oxygen concentration continuously increases, the ruthenium (Ru) concentration decreases.

As a metal contained in the second barrier metal film A5, a refractory metal is preferably used. Thus, in the process step of forming a wire of an upper layer after formation of the second copper wire 14, even when heat of about 400° C. is applied, the second barrier metal film A5 does not degrade due to the heat treatment. Therefore, a highly reliable semiconductor device can be achieved.

When the second barrier metal film A5 has a small thickness, the second barrier metal film A5 does not necessarily have conductivity. However, it is preferable that the second barrier metal film A5 has conductivity. Hereinafter, the second barrier metal film A5 having conductivity will be specifically described.

As a metal forming the barrier metal film A5, titanium (Ti), zirconium (Zr), hafnium (Hf), tantalum (Ta), niobium (Nb), tungsten (W), vanadium (V), molybdenum (Mo), ruthenium (Ru), osmium (Os), rhodium (Rh), iridium (Ir), palladium (Pd) or platinum (Pt) is preferably used.

It is more preferable that as a metal forming the second barrier metal film A5, vanadium (V), molybdenum (Mo), ruthenium (Ru), osmium (Os), rhodium (Ru), iridium (Ir), palladium (Pd), platinum (Pt) or the like is used. Thus, when the metal is oxidized, conductivity is not largely lost (or a resistivity is small), so that the second barrier metal film A5 having a low resistance can be formed.

As has been described, in the semiconductor device according to the fifth embodiment of the present invention, the oxygen concentration in the second barrier metal film A5 of a film containing oxygen as a component element continuously varies in the direction from a surface of the second barrier metal film A5 which is in contact with an insulation film (i.e., the second insulation film 6, the third insulation film 7 and the fourth insulation film 8) to a surface of the second barrier metal film A5 which is in contact with the second copper wire 14. Thus, the second barrier metal film A5 does not have an interface at which a composition is remarkably changed, so that the strength of the second barrier metal film A5 itself can be largely improved. Therefore, a highly reliable semiconductor device including a multi-layer wire with a low resistance and excellent adhesion can be achieved. Furthermore, by increasing the oxygen concentration in the vicinity of the interface between the second barrier metal film A5 and the insulation film (i.e., each of the second insulation film 6, the third insulation film 7 and the fourth insulation film 8), adhesion between the second barrier metal film A5 and the insulation film (i.e., the second insulation film 6, the third insulation film 7 and the fourth insulation film 8) can be improved. Also, by reducing the oxygen concentration in the vicinity of the interface between the second barrier metal film A5 and the second copper wire 14, adhesion between the second barrier metal film A5 and the second copper wire 14 can be improved.

Next, a method for fabricating a semiconductor device according to the fifth embodiment of the present invention will be described with reference to FIG. 14 and FIGS. 15(a) through 15(c). Specifically, a method for fabricating the semiconductor device of FIG. 13 according to the fifth embodiment of the present invention will be hereinafter described.

First, in the same manner as shown in FIG. 2(a) in the first embodiment, a recess portion 10c including a via hole 10a and a wiring groove 10b for dual damascene is formed as shown in FIG. 15(a).

Next, as shown in FIG. 15(b), a second barrier metal film A5 is formed on the second insulation film 6, the third insulation film 7 and the fourth insulation film 8 so as to cover surfaces of the recess portion 10c. In this case, the second barrier metal film A5 is preferably formed by atomic layer deposition (ALD), chemical vapor deposition (CVD), physical vapor deposition (PVD) or like film formation method.

Hereinafter, a method for forming the second barrier metal A5, for example, in the case where the second barrier metal film A5 has an oxygen concentration which continuously varies from ruthenium (Ru) to ruthenium oxide (RuO₂) will be described in detail.

A known atomic layer deposition technique (Journal of The Electrochemical Society, 151, G109-G112 (2004)) is used to form the second barrier metal film A5. Conditions for film formation in this case are as follows. For example, Ru(EtCp)₂ (bis(ethylcyclopentadienyl)ruthenium) gas is used as a source gas of ruthenium (Ru). Where the source gas is heated to 80° C., the source gas is diluted with Ar gas of 50 mL/min (standard temperature and pressure, dry) for use. The temperature of a substrate is 250° C. and the degree of vacuum is 4.56×10² Pa. As oxygen gas, a gas obtained by mixing Ar gas of 100 mL/min (standard temperature and pressure, dry) to oxygen gas of 70 mL/min (standard temperature and pressure, dry) is used. An arbitrary composition in the range from metal ruthenium to ruthenium oxide can be obtained by changing a pulse time used for supplying Ru(EtCp)₂ gas. The range of the pulse time is from 1 second to 10 seconds. After Ru(EtCp)₂ gas is supplied and then purged for a certain period of time, oxygen gas is supplied. When the supply of oxygen gas is stopped, purge is performed for a certain period of time. Thus, a film of a single atomic layer of Ru and O can be grown. This series of steps is assumed to be a cycle. When metal ruthenium is grown, oxygen gas is not supplied.

For example, with the pulse time for supplying Ru(EtCp)₂ continuously changed from 2 seconds to 10 seconds, the second barrier metal film A5 is formed on the second insulation film 6, the third insulation film 7 and the fourth insulation film 9 so as to have a thickness of 10 nm. In the second barrier metal film A5 formed in the above-described manner, a distribution of atomic concentration in the film thickness direction is as shown in FIG. 14. In this manner, the composition of the second barrier metal film A5 can be controlled in a simple manner by changing a pulse time.

Next, a copper film is formed over the second barrier metal film A5 as well as inside the recess portion 10c by copper electroplating so as to fill the recess portion 10c and then parts of the copper film and the second barrier metal film A5 located on the fourth insulation film 8, except for parts thereof located inside the recess portion 10c, are removed by CMP, thereby forming a second copper wire 14 and a via plug which is part of the second copper wire 14. Thus, a semiconductor device having the structure of FIG. 13 can be obtained. A multi-layer wire can be formed by repeating the process steps from film formation of the dielectric barrier film 5 to CMP.

As has been described, according to the method for fabricating a semiconductor device according to the fifth embodiment of the present invention, the second barrier metal film A5 of which an oxygen element concentration continuously varies in the film thickness direction can be formed in a simple manner. Moreover, the same effects as those of the semiconductor device of the fifth embodiment can be achieved. Specifically, in the second barrier metal film A5 of a film containing oxygen as a component element, the concentration of oxygen continuously varies in the direction from a surface of the second barrier metal film A5 which is in contact with an insulation film (i.e., each of the second insulation film 6, the third insulation film 7 and the fourth insulation film 8) to a surface of the second barrier metal film A5 which is in contact with the second copper wire 14. Thus, the second barrier metal film A5 does not have an interface at which a composition is remarkably changed, so that the strength of the second barrier metal film A5 itself can be largely improved. Therefore, a highly reliable semiconductor device including a multi-layer wire with a low resistance and excellent adhesion can be achieved. Furthermore, by increasing the oxygen concentration in the vicinity of the interface between the second barrier metal film A5 and the insulation film (i.e., each of the second insulation film 6, the third insulation film 7 and the fourth insulation film 8), adhesion between the second barrier metal film A5 and the insulation film (i.e., the second insulation film 6, the third insulation film 7 and the fourth insulation film 8) can be improved. Also, by reducing the oxygen concentration in the vicinity of the interface between the second barrier metal film A5 and the second copper wire 14, adhesion between the second barrier metal film A5 and the second copper wire 14 can be improved.

In each of the above-described first through fifth embodiments, the case where a dual damascene structure is adopted has been described. However, needless to say, even when a single damascene structure is adopted, the same effects as those in the case of adoption of a dual damascene structure can be achieved. When a single damascene structure is adopted, a wire and a via plug are formed in separate steps. In such a case, the wire and the via plug are included in a buried wire, i.e., the second copper wire 14 of each of the first through fifth embodiments.

### INDUSTRIAL APPLICABILITY

As has been described, the present invention is useful to a semiconductor device including a barrier metal film with a low resistance and excellent adhesion and a method for fabricating the semiconductor device.

1. A semiconductor device comprising:
an insulation film formed on a substrate;
a buried wire formed in the insulation film; and
a barrier metal film formed between the insulation film and the buried wire,
wherein the barrier metal film is formed of a metal oxide film, a transition layer and a metal film stacked in this order in the direction from a side of the barrier metal film at which the insulation film exists to a side thereof at which the buried wire exists, and
wherein the transition layer is formed of a single atomic layer having substantially an intermediate composition between respective compositions of the metal oxide film and the metal film.

2. The semiconductor device of claim 1, wherein a metal forming the metal oxide film and a metal forming the metal film are different elements.

3. The semiconductor device of claim 1, wherein a metal forming the metal oxide film and a metal forming the metal film are the same element.

4. A semiconductor device comprising:
an insulation film formed on a substrate;
a buried wire formed in the insulation film; and
a barrier metal film formed between the insulation film and the buried wire,
wherein the barrier metal film is formed of a metal oxide film, a transition layer and a metal film stacked in this order in the direction from a side of the barrier metal film at which the insulation film exists to a side thereof at which the buried wire exists, and
wherein the transition layer is formed of a plurality of atomic layers having substantially an intermediate composition between respective compositions of the metal oxide film and the metal film.

5. The semiconductor device of claim 4, wherein a metal forming the metal oxide film and a metal forming the metal film are different elements.

6. The semiconductor device of claim 4, wherein a metal forming the metal oxide film and a metal forming the metal film are the same element.

7. A semiconductor device comprising:
an insulation film formed on a substrate;
a buried wire formed in the insulation film; and
a barrier metal film formed between the insulation film and the buried wire,
wherein the barrier metal film is formed of a transition layer and a metal film stacked in this order in the direction from a side of the barrier metal film at which the insulation film exists to a side thereof at which the buried wire exists, and
wherein the transition layer is formed of a single atomic layer including a metal oxide and a metal forming the metal film and having substantially an intermediate composition between respective compositions of the metal oxide and the metal film.

8. The semiconductor device of claim 7, wherein a metal forming the metal oxide and a metal forming the metal film are different elements.

9. The semiconductor device of claim 7, wherein a metal forming the metal oxide and a metal forming the metal film are the same element.

10. A semiconductor device comprising:
an insulation film formed on a substrate;
a buried wire formed in the insulation film; and
a barrier metal film formed between the insulation film and the buried wire,
wherein the barrier metal film is formed of a transition layer and a metal film stacked in this order in the direction from a side of the barrier metal film at which the insulation film exists to a side thereof at which the buried wire exists, and
wherein the transition layer is formed of a plurality of atomic layers including metal oxide and a metal forming the metal film and having substantially an intermediate composition between respective compositions of the metal oxide and the metal film.

11. The semiconductor device of claim 10, wherein a metal forming the metal oxide and a metal forming the metal film are different elements.

12. The semiconductor device of claim 10, wherein a metal forming the metal oxide and a metal forming the metal film are the same element.

13. A semiconductor device comprising:
an insulation film formed on a substrate;
a buried wire formed in the insulation film; and
a barrier metal film formed between the insulation film and the buried wire,
wherein the barrier metal film contains oxygen as a component element, and
wherein a concentration of oxygen contained in the barrier metal film continuously varies in a film thickness direction of the barrier metal film.

14. A method for fabricating a semiconductor device, the method comprising the steps of:
forming a recess portion in an insulation film provided on a substrate;
forming a barrier metal film including a metal oxide film, a transition layer and a metal film stacked in this order so that the barrier metal film covers surfaces of the recess portion; and
forming a buried wire on the barrier metal film so that the recess portion is filled,
wherein the step of forming the barrier metal film includes the step of performing a single cycle of deposition by atomic layer deposition, thereby forming the transition layer of a single atomic layer having substantially an intermediate composition between respective compositions of the metal oxide film and the metal film.

15. The method of claim 14, wherein a metal forming the metal oxide film and a metal forming the metal film are different elements.

16. The method of claim 14, wherein a metal forming the metal oxide film and a metal forming the metal film are the same element.

17. A method for fabricating a semiconductor device, the method comprising the steps of:
forming a recess portion in an insulation film provided on a substrate;
forming a barrier metal film including a metal oxide film, a transition layer and a metal film stacked in this order so that the barrier metal film covers surfaces of the recess portion; and
forming a buried wire on the barrier metal film so that the recess portion is filled,
wherein the step of forming the barrier metal film includes the step of performing a plurality of cycles of deposition by atomic layer deposition, thereby forming the transition layer including a plurality of atomic layers having substantially an intermediate composition between respective compositions of the metal oxide film and the metal film.

18. The method of claim 17, wherein a metal forming the metal oxide film and a metal forming the metal film are different elements.

19. The method of claim 17, wherein a metal forming the metal oxide film and a metal forming the metal film are the same element.

20. A method for fabricating a semiconductor device, the method comprising the steps of:
forming a recess portion in an insulation film provided on a substrate;
forming a barrier metal film including a transition layer and a metal film stacked in this order so that the barrier metal film covers surfaces of the recess portion; and
forming a buried wire on the barrier metal film so that the recess portion is filled,
wherein the step of forming the barrier metal film includes the step of performing a single cycle of deposition by atomic layer deposition, thereby forming the transition layer made of a single atomic layer including a metal oxide and a metal forming the metal film and having substantially an intermediate composition between respective compositions of the metal oxide and the metal film.

21. The method of claim 20, wherein a metal forming the metal oxide and a metal forming the metal film are different elements.

22. The method of claim 20, wherein a metal forming the metal oxide and a metal forming the metal film are the same element.

23. A method for fabricating a semiconductor device, the method comprising the steps of:
forming a recess portion in an insulation film provided on a substrate;
forming a barrier metal film including a transition layer and a metal film stacked in this order so that the barrier metal film covers surfaces of the recess portion; and
forming a buried wire on the barrier metal film so that the recess portion is filled,
wherein the step of forming the barrier metal film includes the step of performing a plurality of cycles of deposition by atomic layer deposition, thereby forming the transition layer including a plurality of atomic layers made of a metal forming a metal oxide and the metal film and having an intermediate composition between respective compositions of the metal oxide and the metal film.

24. The method of claim 23, wherein a metal forming the metal oxide and a metal forming the metal film are different elements.

25. The method of claim 23, wherein a metal forming the metal oxide and a metal forming the metal film are the same element.

26. A method for fabricating a semiconductor device, the method comprising the steps of:
forming a recess portion in an insulation film provided on a substrate;
forming a barrier metal film containing oxygen as a component element so that the barrier metal film covers surfaces of the recess portion; and
forming a buried wire on the barrier metal film so that the recess portion is filled,
wherein the step of forming the barrier metal film includes the step of forming the barrier metal such that a concentration of oxygen contained in the barrier metal film continuously varies in a film thickness direction of the barrier metal film.
